(19) United States
(12) Patent Application Publication
(10) Pub. No.: US 2026/0011659 A1
(43) Pub. Date: Jan. 8, 2026

(54) SEMICONDUCTOR DEVICE INCLUDING GUARD RING AND TRENCH STRUCTURES

(71) Applicant: SAMSUNG ELECTRONICS CO., LTD., SUWON-SI (KR)

(72) Inventors: Woongkee KIM, Suwon-si (KR); Hyunggyun NOH, Suwon-si (KR); Wonhong CHOI, Suwon-si (KR)

(21) Appl. No.: 19/006,410

(22) Filed: Dec. 31, 2024

(30) Foreign Application Priority Data
Jul. 3, 2024 (KR) 10-2024-0087537

(51) Int. Cl. H01L 23/58; H01L 23/00; H01L 23/522; H01L 23/544

(52) U.S. Cl. CPC H01L 23/585; H01L 23/5226; H01L 23/544; H01L 23/562; H01L 2223/5446

(57) ABSTRACT

A semiconductor device includes: a substrate including a main chip area and a scribe lane area, wherein chip circuits are disposed in the main chip area, and the scribe lane area surrounds the main chip area; a first insulating layer disposed on the substrate; a second insulating layer disposed on the first insulating layer and in which a plurality of guard rings are embedded; a dielectric layer disposed on the second insulating layer; and a third insulating layer disposed on the dielectric layer, wherein the scribe lane area includes a first area and a second area, wherein the first area is adjacent to the main chip area based on a decreasing point of a thickness of the third insulating layer, wherein the plurality of guard rings includes a first guard ring disposed in the first area and a second guard ring disposed in the second area.

### CROSS-REFERENCE TO RELATED APPLICATION

This application claims priority under 35 U.S.C. § 119 to Korean Patent Application No. 10-2024-0087537, filed on Jul. 3, 2024, in the Korean Intellectual Property Office, the disclosure of which is incorporated by reference herein in its entirety.

### TECHNICAL FIELD

Example embodiments of the present inventive concept relate to a semiconductor device, and more particularly, to a semiconductor device including a guard ring and trench structures.

### DISCUSSION OF THE RELATED ART

Generally, chip areas that are formed on a substrate, such as a wafer, may be divided by a scribe lane. Typically, by cutting the substrate along the scribe lane, individual chips may be fabricated.

To fabricate individual chips, a multilayer first insulating layer and a circuit structure may be formed on the substrate. However, in harsh conditions such as high temperature and high humidity environments, interfacial delamination within the first insulating layer may occur, which may decrease product reliability.

### SUMMARY

According to example embodiments of the present inventive concept, a semiconductor device includes: a substrate that includes a main chip area and a scribe lane area, wherein chip circuits, which include a first chip circuit and a second chip circuit, are disposed in the main chip area, and the scribe lane area is configured to surround the main chip area; a first insulating layer that is disposed on the substrate and in which the first chip circuit is embedded; a second insulating layer that is disposed on the first insulating layer and in which the second chip circuit and a plurality of guard rings are embedded; a dielectric layer that is disposed on the second insulating layer and in which a metal plug is embedded; and a third insulating layer that is disposed on the dielectric layer, wherein the scribe lane area includes a first area and a second area, wherein the first area is adjacent to the main chip area based on a decreasing point of a thickness of the third insulating layer, and the second area is an area other than the first area, wherein the plurality of guard rings includes a first guard ring and a second guard ring including a first second guard ring, wherein the first guard ring is connected to the metal plug, and the first second guard ring is not connected to the metal plug, and wherein the first guard ring is disposed in the first area, and the first second guard ring is disposed in the second area.

According to example embodiments of the present inventive concept, a semiconductor device includes: a substrate that includes a main chip area and a scribe lane area, wherein chip circuits, which include a first chip circuit and a second chip circuit, are disposed in the main chip area, and the scribe lane area is configured to surround the main chip area; a first insulating layer that is disposed on the substrate and in which the first chip circuit is embedded; a second insulating layer that is disposed on the first insulating layer and in which the second chip circuit and a plurality of guard rings are embedded; and a third insulating layer that is disposed on the second insulating layer, wherein, in the scribe lane area, a trench structure configured to penetrate the first insulating layer and the second insulating layer is formed, and the scribe lane area includes an X area, which is adjacent to the main chip area based on the trench structure, and a Y area that is an area other than the X area, wherein the plurality of guard rings includes a first guard ring and a second guard ring, and wherein the first guard ring is disposed in the X area, and the second guard ring is disposed in the Y area.

According to example embodiments of the present inventive concept, a semiconductor device includes: a substrate that includes a main chip area and a scribe lane area, wherein chip circuits, which includes a first chip circuit and a second chip circuit, are disposed in the main chip area, and the scribe lane area is configured to surround the main chip area; a first insulating layer that is disposed on the substrate and in which the first chip circuit is embedded; a second insulating layer that is disposed on the first insulating layer and in which the second chip circuit and a plurality of guard rings are embedded; a dielectric layer that is disposed on the second insulating layer and in which a metal plug is embedded; a third insulating layer that is disposed on the dielectric layer; a silicate layer that is disposed between the second insulating layer and the dielectric layer and that is in contact with the second insulating layer; and a photosensitive insulating film disposed on a portion of the third insulating layer, wherein a trench structure is formed in the scribe lane area, wherein the trench structure is configured to penetrate the first insulating layer and the second insulating layer, to gradually decrease in length in a first direction, which is parallel to a surface of the substrate, as the trench structure extends in a direction from the second insulating layer to the first insulating layer, and to surround at least a portion of a corner of the main chip area while being spaced apart from the main chip area, wherein the scribe lane area includes an X area and a Y area, wherein the X area is adjacent to the main chip area based on the trench structure, and the Y area is an area other than the X area, wherein the plurality of guard rings includes a first guard ring and a second guard ring, wherein the first guard ring is disposed in the X area, and the second guard ring is disposed in the Y area, wherein the first guard ring is configured to penetrate at least a portion of the second insulating layer, wherein the second guard ring includes a protrusion structure and is configured to penetrate at least a portion of the silicate layer, wherein the protrusion structure includes an axial protrusion and a transverse protrusion, wherein the axial protrusion extends in a second direction intersecting the first direction, and the transverse protrusion intersects the axial protrusion, wherein the second guard ring is of a plurality of second guard rings, wherein the plurality of guard rings further includes a bridge configured to connect at least two of the plurality of second guard rings to each other, and wherein the photosensitive insulating film is configured to fill the trench structure.

### BRIEF DESCRIPTION OF THE DRAWINGS

The above and other aspects and features of the present inventive concept will become more apparent by describing in detail embodiments thereof with reference to the attached drawings, in which:

FIG. 1 is a cross-sectional view illustrating a semiconductor device according to an example embodiment of the present inventive concept;

FIG. 2 is a cross-sectional view illustrating a semiconductor device including a first guard ring that penetrates a portion of a silicate layer and a second guard ring that penetrates a portion of a dielectric layer, according to an example embodiment of the present inventive concept;

FIG. 3 is a cross-sectional view illustrating a semiconductor device including a bridge connecting second guard rings, according to an example embodiment of the present inventive concept;

FIG. 4 is a cross-sectional view illustrating a semiconductor device including a bridge connecting second guard rings, according to an example embodiment of the present inventive concept;

FIG. 5 is a cross-sectional view illustrating a semiconductor device including a bridge connecting second guard rings that penetrate a portion of a dielectric layer, according to an example embodiment of the present inventive concept;

FIG. 6 is a cross-sectional view illustrating a semiconductor device including a trench structure, according to an example embodiment of the present inventive concept;

FIG. 7 is a cross-sectional view illustrating a semiconductor device including a trench structure and a bridge connecting second guard rings, according to an example embodiment of the present inventive concept;

FIG. 8 is a cross-sectional view illustrating a semiconductor device including a photosensitive insulating film filling a trench structure, according to an example embodiment of the present inventive concept;

FIG. 9 is a cross-sectional view illustrating a semiconductor device including a photosensitive insulating film filling a trench structure and a bridge connecting second guard rings, according to an example embodiment of the present inventive concept;

FIG. 10 is a cross-sectional view illustrating a semiconductor device including a trench structure and a second guard ring that penetrates a portion of a dielectric layer, according to an example embodiment of the present inventive concept;

FIG. 11 is a cross-sectional view illustrating a semiconductor device including a trench structure and a bridge connecting second guard rings that penetrate a portion of a dielectric layer, according to an example embodiment of the present inventive concept;

FIG. 12 is a cross-sectional view illustrating a semiconductor device including a photosensitive insulating film filling a trench structure and a second guard ring that penetrates a portion of a dielectric layer, according to an example embodiment of the present inventive concept;

FIG. 13 is a cross-sectional view of a semiconductor device including a photosensitive insulating film filling a trench structure and a bridge connecting second guard rings that penetrate a portion of a dielectric layer, according to an example embodiment of the present inventive concept;

FIG. 14 is a top plan view illustrating a substrate of a semiconductor device according to an example embodiment of the present inventive concept;

FIG. 15 is an enlarged top plan view illustrating a substrate of a semiconductor device according to an example embodiment of the present inventive concept;

FIG. 16 is a cross-sectional view illustrating a semiconductor device including a trench structure, according to an example embodiment of the present inventive concept;

FIG. 17 is a cross-sectional view illustrating a semiconductor device including a trench structure and a bridge connecting second guard rings, according to an example embodiment of the present inventive concept;

FIG. 18 is a cross-sectional view illustrating a semiconductor device including a trench structure and a bridge connecting second guard rings, according to an example embodiment of the present inventive concept;

FIG. 19 is a cross-sectional view illustrating a semiconductor device including a photosensitive insulating film filling a trench structure, according to an example embodiment of the present inventive concept;

FIG. 20 is a cross-sectional view illustrating a semiconductor device including a photosensitive insulating film filling a trench structure and a bridge connecting second guard rings, according to an example embodiment of the present inventive concept;

FIG. 21 is a cross-sectional view illustrating a semiconductor device including a trench structure and a second guard ring that penetrates a portion of a dielectric layer, according to an example embodiment of the present inventive concept;

FIG. 22 is cross-sectional view illustrating a semiconductor device including a trench structure and a bridge connecting second guard rings that penetrate a portion of a dielectric layer, according to an example embodiment of the present inventive concept;

FIG. 23 is a cross-sectional view illustrating a semiconductor device including a trench structure and a second guard ring that penetrates a portion of a dielectric layer, according to an example embodiment of the present inventive concept;

FIG. 24 is a cross-sectional view illustrating a semiconductor device including a trench structure and a bridge connecting second guard rings that penetrate a portion of a dielectric layer, according to an example embodiment of the present inventive concept;

FIG. 25 is a perspective view illustrating a second guard ring according to an example embodiment of the present inventive concept;

FIG. 26 is a perspective view illustrating a semiconductor device including a second guard ring (dotted line), according to an example embodiment of the present inventive concept;

FIG. 27 is perspective view illustrating a semiconductor device including second guard rings (dotted line) connected by a bridge, according to example embodiments of the present inventive concept;

FIG. 28 is a perspective view illustrating a semiconductor device including second guard rings (dotted line) connected by a bridge, according to example embodiments of the present inventive concept; and

FIG. 29 is a perspective view illustrating a semiconductor device including second guard rings (dotted line) connected by bridges, according to example embodiments of the present inventive concept.

### DETAILED DESCRIPTION OF THE EMBODIMENTS

It is to be understood that the words and terminologies that are used in the specification and claims are not to be construed as limited to common or dictionary meanings but construed as meanings and conceptions coinciding with the technical spirit of the present disclosure under a principle that the inventor(s) may appropriately define the conception of the terminologies to explain the invention.

In the specification and figures, like reference numerals may denote like elements or features, and thus, repetitive descriptions may be omitted.

In the drawings, various thicknesses, lengths, and angles are shown and while the arrangement shown does indeed represent an embodiment of the present inventive concept, it is to be understood that modifications of the various thicknesses, lengths, and angles may be possible within the spirit and scope of the present inventive concept and the present inventive concept is not necessarily limited to the particular thicknesses, lengths, and angles shown. Further, in a coordinate system shown in the drawings, each axis may be perpendicular to one another, and a direction pointed by an arrow may be a positive (+) direction. A directly opposite direction (a direction turned by 180 degrees) to the direction pointed by the arrow may be a negative (−) direction.

When an element is referred to as being “directly on,” “contacting,” or “in contact with” another element herein, it may be understood that the element may be in direct contact with or directly connected to another element or there are no intervening elements present in between.

Further, when an element is referred to as being “above” or “on an upper surface of” another element in the specification, it may be understood that the element is present above based on a vertical direction or, for example, above based on direction +D1 in a drawing, and it may be understood that the element may be in direct contact with or directly connected to another element or an intervening element may be present in between. It will be understood that when an element or layer is referred to as being “on” another element or layer, the element or layer may be directly on another element or layer or intervening elements or layers may be present.

Further, when an element is referred to as being “below” or “on a lower surface of” another element in the specification, it may be understood that the element is present below based on a vertical direction or, for example, below based on direction −D1 in a drawing, and it may be understood that the element may be in direct contact with or directly connected to another element or an intervening element may be present in between.

Other similar expressions describing positional relationships between elements may also be similarly construed as above.

In the descriptions below, a singular expression and/or element includes a plural expression and/or element unless context clearly dictates otherwise.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, in the example, terms “below” and “beneath” may encompass both an orientation of above, below and beneath. The device may be otherwise oriented (e.g., rotated 90 degrees or at other orientations) and the spatially relative descriptors used herein may be interpreted accordingly.

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section.

Embodiments of the present inventive concept relate to a semiconductor device that addresses reliability and structural issues during manufacturing and operation. Specifically, the semiconductor device includes a substrate with a main chip area for circuits and a surrounding scribe lane area, incorporating multiple insulating and dielectric layers to increase performance and resilience. A guard ring system and trench structures may be used to increase durability and prevent interfacial delamination, particularly in challenging conditions like high humidity and temperature.

The guard rings may be divided into first and second types. The first guard rings, connected to metal plugs, are placed near the main chip area to prevent damage during substrate cutting. The second guard rings, featuring unique protrusion structures, are placed farther from the chip area to distribute thermal stress, minimizing delamination risks. The system also integrates bridges connecting these guard rings, increasing structural integrity.

The trench structure may penetrate various layers of the device, isolating stress from the main chip area and further increasing product reliability. The trenches may be filled with a photosensitive insulating film, which adds additional stability and insulation. This layered and structured approach may increase reliability of the semiconductor device for use in applications like memory chips, processors, and communication devices.

Accordingly, a semiconductor device with increased product reliability by preventing interfacial delamination among a first insulating layer may be provided. Further, damage applied to a scribe lane while cutting a substrate may be prevented from spreading to a chip area.

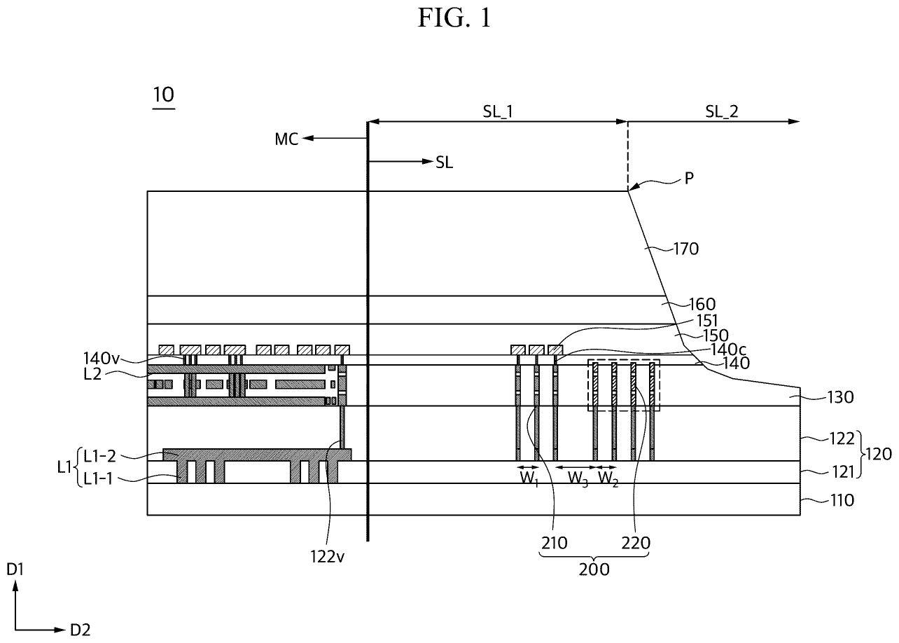

FIG. 1 is a cross-sectional view illustrating a semiconductor device 10 according to an example embodiment of the present inventive concept.

The semiconductor device 10 according to an example embodiment of the present inventive concept may be used for various product groups. For example, the semiconductor device 10 may be used for random-access memory (RAM) such as dynamic random-access memory (DRAM) and static random-access memory (SRAM), flash memory such as NOR flash and NAND flash, an application processor (AP) of a mobile device, a central processing unit (CPU) of a computer, a digital signal processor (DSP) which processes digital signals, a light emitting diode, a complementary metal oxide semiconductor (CMOS) which changes light into image signals, an image sensor, a display driver integrated circuit (DDI), or other communication devices.

In an example, the semiconductor device 10 may include a substrate 110. The substrate 110 may be a silicon wafer, for example. The substrate 110 may include a main chip area MC, where chip circuits including a first chip circuit L1 and a second chip circuit L2 are disposed, and a scribe lane area SL configured to surround the main chip area MC. A plurality of the main chip areas MC may be provided and each main chip area MC may be divided by the scribe lane area SL. In other words, the substrate 110 may have a shape in which the scribe lane area SL surrounds each main chip area MC individually.

In an example, the first chip circuit L1 and the second chip circuit L2 may be disposed in different layers. The first chip circuit L1 and the second chip circuit L2 may be electrically connected to each other and may transmit and receive electric signals.

In an example, the first chip circuit L1 and the second chip circuit L2 may include conductive metals. For example, each of the first chip circuit L1 and the second chip circuit L2 may include, but are not limited to, gold (Au), silver (Ag), copper (Cu), or aluminum (Al).

In an example, the semiconductor device 10 may include a first insulating layer 120 that is disposed on an upper surface of the substrate 110. The first insulating layer 120 may be a layer generally called inter-layer dielectrics (ILD).

In an example, the first insulating layer 120 may include a low dielectric constant (low-k) material of which a dielectric constant is smaller than a dielectric constant of silicon dioxide (SiO₂).

In the present disclosure, the low dielectric constant material may include one or more of silicon nitride (SiN), hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, and/or aluminum oxide, for example, but is not limited thereto as long as a dielectric constant is smaller than the dielectric constant of silicon dioxide (SiO₂).

In an example, the first insulating layer 120 may be formed as, but not limited to, a multilayer structure and may also be formed as a single layer. In addition, the first insulating layer 120 may include a 1-1 insulating layer 121 disposed on an upper surface of the substrate 110 and a 1-2 insulating layer 122 disposed on an upper surface of the 1-1 insulating layer 121. For example, the 1-1 insulating layer 121 may be in contact with the substrate 110, and the 1-2 insulating layer 122 may be in contact with the 1-1 insulating layer 121.

In an example, the first chip circuit L1 may include a 1-1 chip circuit L1-1, which is embedded in the 1-1 insulating layer 121, and a 1-2 chip circuit L1-2, which is embedded in the 1-2 insulating layer 122. The 1-1 chip circuit L1-1 may be connected to the substrate 110. The 1-2 chip circuit L1-2 may be electrically connected to the 1-1 chip circuit L1-1. For example, the 1-1 chip circuit L1-1 and the 1-2 chip circuit L1-2 may be connected to each other and may be a single integrated body.

In an example, a via 122v electrically connected to the 1-2 chip circuit L1-2 may be disposed in the 1-2 insulating layer 122. The via 122v may be embedded in the 1-2 insulating layer 122. The via 122v may be surrounded by the 1-2 insulating layer 122. The via 122v may penetrate the 1-2 insulating layer 122. The via 122v may electrically connect the first chip circuit L1 and the second chip circuit L2 to each other. The via 122v may include a conductive metal.

In an example, the semiconductor device 10 may include a second insulating layer 130 disposed on an upper surface of the first insulating layer 120. The second insulating layer 130 may be a layer generally called inter-metal dielectrics (IMD).

In an example, the second insulating layer 130 may include a low dielectric constant (low-k) material of which a dielectric constant is smaller than a dielectric constant of silicon dioxide (SiO₂).

In an example, the second insulating layer 130 may include an inclined area in the scribe lane area SL. The inclined area in the second insulating layer 130 may be formed in a cutting process and continue to decrease in thickness from a decreasing point of thickness in a direction farther from the main chip area MC. For example, the inclined area in the second insulating layer 130 may decrease in thickness as the distance from the main chip area MC increases.

In the present disclosure, a thickness may represent a length based on a first direction perpendicular to a surface of the substrate 110. For example, the first direction may be D1 in FIG. 1, and a length based on the first direction D1 may be referred to as thickness. In addition, when an element is described herein as more adjacent to or farther from the main chip area MC, it may be represented that the element is more adjacent or farther based on a second direction D2 parallel to the surface of the substrate 110. For example, with respect to a boundary between the main chip area MC and the scribe line SL, regarding the second direction may be D2 in FIG. 1, going in direction +D2 may be farther from the main chip area MC (e.g., extending in a direction away from the main chip area MC), and going in direction −D2 may be more adjacent to the main chip area MC (e.g., extending in a direction toward the main chip area MC). Further, in the present disclosure, a third direction (that is, D3) may represent a direction parallel to the surface of the substrate 110 and perpendicular to the second direction (that is, D2).

In an example, the second chip circuit L2 may be embedded in the second insulating layer 130. The second chip circuit L2 embedded in the second insulating layer 130 may be connected to the via 122v described above and electrically connected to the first chip circuit L1 through the via 122v.

In an example, a guard ring 200 may be disposed within the second insulating layer 130. The guard ring 200 may be embedded in the second insulating layer 130. The guard ring 200 may be disposed within the scribe lane area SL.

In an example, the guard ring 200 may penetrate at least a portion of the first insulating layer 120. Further, for example, the guard ring 200 may be an integral form (e.g., a single unified structure) and may be embedded in the second insulating layer 130 while penetrating at least a portion of the first insulating layer 120. For example, the guard ring 200 may penetrate the second insulating layer 130 and the first insulating layer 120. In addition, for example, the guard ring 200 may be divided into a plurality of areas to be separated and combined and may also have an integral form through combination. Further, the guard ring 200 may penetrate the 1-2 insulating layer 122. Furthermore, the guard ring 200 may penetrate a portion of the 1-1 insulating layer 121.

In an example, the semiconductor device 10 may include a silicate layer 140 disposed on an upper surface of the second insulating layer 130. The silicate layer 140 may be disposed between the second insulating layer 130 and a dielectric layer 150 to be described below and may be in contact with the second insulating layer 130. The silicate layer 140 may include silicate and may include tetraethyl orthosilicate (TEOS), for example.

In an example, the silicate layer 140 may include an inclined area in the scribe lane area SL. The inclined area in the silicate layer 140 may be formed in a cutting process and continue to decrease in thickness from a decreasing point of thickness in a direction away from the main chip area MC.

In an example, the silicate layer 140 may have a via 140v disposed in the main chip area MC. The via 140v may be embedded in the silicate layer 140. The via 140v may be surrounded by the silicate layer 140. The via 140v may penetrate the silicate layer 140. In addition, the via 140v may be electrically connected to the second chip circuit L2. The via 140v may include a conductive metal.

In an example, the silicate layer 140 may have a connecting object 140c disposed in the scribe lane area SL. The connecting object 140c may be embedded in the silicate layer 140. The connecting object 140c may include conductive material and may be a via.

In an example, the semiconductor device 10 may include the dielectric layer 150 disposed on the upper surface of the second insulating layer 130. The dielectric layer 150 may be disposed on an upper surface of the silicate layer 140 and may be in contact therewith.

In an example, a metal plug 151 may be embedded in the dielectric layer 150. The metal plug 151 may include a conductive metal. The metal plug 151 may be electrically connected to the second chip circuit L2 through the via 140v that is embedded in the silicate layer 140. In addition, the metal plug 151 may be connected to the connecting object 140c.

In an example, the dielectric layer 150 may include an inclined area in the scribe lane area SL. The inclined area in the dielectric layer 150 may be formed in a cutting process and continue to decrease in thickness from a decreasing point of thickness in a direction away from the main chip area MC.

In an example, the dielectric layer 150 may include, but is not limited to, one or more of metal oxide, metal oxynitride, metal silicon oxide, and/or metal silicon oxynitride. In addition, the dielectric layer 150 may be a layer formed as a high-density plasma (HDP) manner is applied. For example, the dielectric layer 150 may include oxide formed through HDP chemical vapor deposition (CVD).

In an example, the semiconductor device 10 may include a third insulating layer 170 disposed on an upper surface of the dielectric layer 150. In another example, the third insulating layer 170 may be disposed on the upper surface of the second insulating layer 130. The third insulating layer 170 may include, but is not limited to, one or more of silicate (for example, TEOS) described above, a low dielectric constant (low-k) material, metal oxide, metal oxynitride, metal silicon oxide, and/or metal silicon oxynitride.

In an example, the third insulating layer 170 may include an inclined area in the scribe lane area SL. The inclined area in the third insulating layer 170 may be formed in a cutting process and continue to decrease in thickness from a decreasing point P of thickness in a direction away from the main chip area MC.

In an example, the scribe lane area SL may include a first area SL_1 adjacent to the main chip area MC based on the decreasing point P of the thickness of the third insulating layer 170 and a second area SL_2 that is an area other than the first area SL_1. For example, the first area SL_1 may be disposed between the main chip area MC and the second area SL_2. Here, the guard ring 200 may include a first guard ring 210 and a second guard ring 220. At least one first guard ring 210 may be disposed in the first area SL_1, and at least one second guard ring 220 may be disposed in the second area SL_2. At least one second guard ring 220 disposed in the second area SL_2 may be the first second guard ring. The second guard ring 220 may include the first second guard ring. The first guard ring 210 may be embedded in the second insulating layer 130. The second guard ring 220 may be embedded in the second insulating layer 130.

In an example, the third insulating layer 170 may have a uniform thickness in the first area SL_1 and include an inclined area in the second area SL_2, and the inclined area may continue to decrease in thickness from the decreasing point P of thickness in the direction away from the main chip area MC.

In an example, the first guard ring 210 may be connected to the metal plug 151. The first guard ring 210 may be connected to the connecting object 140c embedded in the silicate layer 140, and the first guard ring 210 and the metal plug 151 may be connected to each other through the connecting object 140c.

In an example, the second guard ring 220 might not be connected to the metal plug 151. The connecting object 140c embedded in the silicate layer 140 might not be disposed in a position corresponding to the second guard ring 220, or even though the connecting object 140c is present, the connecting object 140c might not be connected to the second guard ring 220 and/or the metal plug 151.

In an example, the first guard ring 210 and the second guard ring 220 may be divided according to whether or not it is connected to the metal plug 151. In other words, the guard ring 200 connected to the metal plug 151 may be sorted into the first guard ring 210, and the guard ring 200 not connected to the metal plug 151 may be sorted into the second guard ring 220.

In an example, at least another second guard ring 220 may be disposed in the first area SL_1. In other words, the first area SL_1 may have at least another second guard ring 220 disposed therein. At least another second guard ring 220 may be disposed in each of the first area SL_1 and the second area SL_2. At least another second guard ring 220 disposed in the first area SL_1 may be the second second guard ring. The second guard ring 220 may include the second second guard ring.

In an example, the first guard ring 210 may be disposed more adjacent to the main chip area MC than the second guard ring 220 that is disposed in the first area SL_1. In addition, the second guard ring 220 disposed in the first area SL_1 may be disposed in succession with the second guard ring 220 disposed in the second area SL_2. Here, being in succession may represent maintaining a pattern without an intervening structure in between.

In an example, the first guard ring 210 may prevent damage (e.g., cracks and fractures), which may have been applied to the scribe lane area SL while cutting the substrate 110, from spreading to the main chip area MC. For example, the first guard ring 210 may referred to as a dam structure.

In an example, the first guard ring 210 may penetrate at least a portion of the silicate layer 140. Through this, damage that may be applied to the scribe lane area SL while cutting the substrate 110 may be more effectively prevented from spreading to the main chip area MC.

In an example, the first guard ring 210 may be plural. Through this, damage that may be applied to the scribe lane area SL while cutting the substrate 110 may be more effectively prevented from spreading to the main chip area MC.

In an example, the second guard ring 220 may help increase product reliability by preventing interfacial delamination of the second insulating layer 130. In the second insulating layer 130, a thermal stress-concentrated portion may be formed due to material properties in harsh conditions such as high temperature and high humidity environments and interfacial delamination may be generated due to the concentrated thermal stress. The second guard ring 220 may be disposed in a position where thermal stress may be concentrated to distribute the thermal stress and prevent interfacial delamination.

In an example, the second guard ring 220 may be plural. By the second guard ring 220 being provided in plural, interfacial delamination of the second insulating layer 130 may be prevented. For example, the number of the second guard rings 220 may be more than the number of the first guard rings 210.

In an example, a plurality of first guard rings 210 and a plurality of second guard rings 220 may be provided. In addition, based on the second direction D2 parallel to the surface of the substrate 110, a gap W2 between the second guard rings 220 that are adjacent to each other may be identical to a gap W1 between the first guard rings 210 that are adjacent to each other. Through this, productivity may be secured for easy and efficient manufacturing process design.

In an example, based on the second direction D2 parallel to the surface of the substrate 110, a gap W3 between the first guard ring 210 and the second guard ring 220 that are adjacent to each other may be greater than each of the gap W1 between the first guard rings 210 that are adjacent to each other and the gap W2 between the second guard rings 220 that are adjacent to each other.

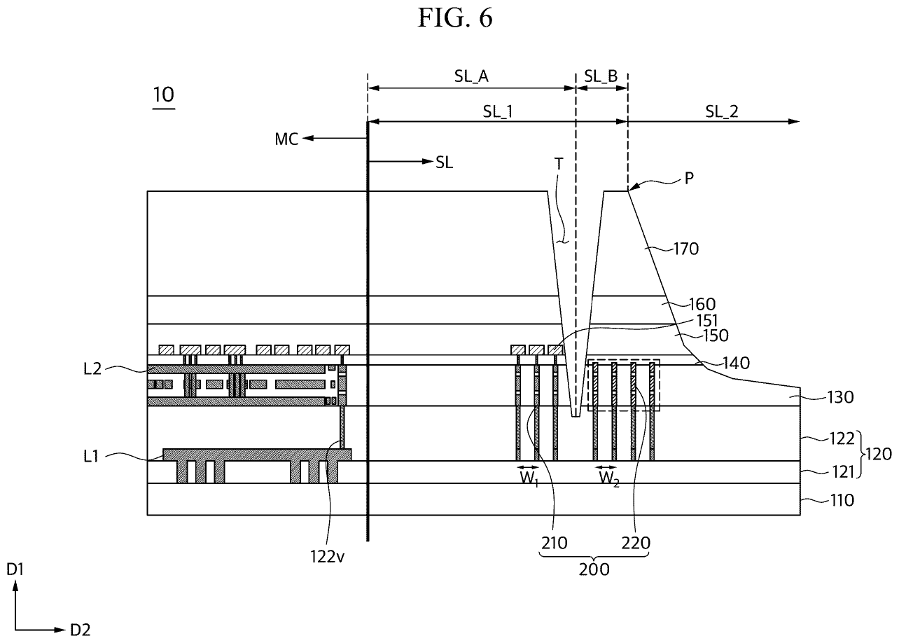

In an example, a trench structure (see T of FIG. 6) to be described below may be formed between the first guard ring 210 and the second guard ring 220 that are adjacent to each other. In addition, the guard ring 200 may include a third guard ring between the first guard ring 210 and the second guard ring 220 that are adjacent to each other. The third guard ring may be exposed by the trench structure (see T of FIG. 6) to be described below.

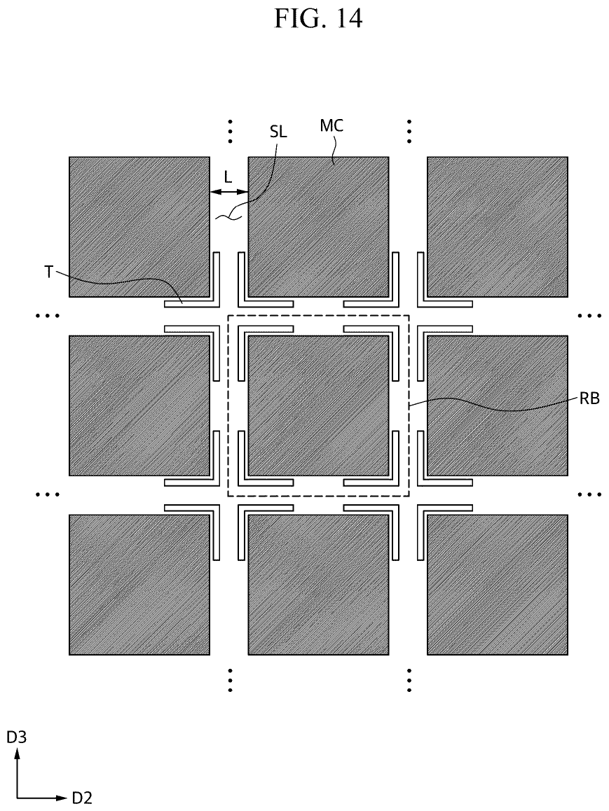

In an example, based on the second direction D2 parallel to the surface of the substrate 110, the gap W2 between the second guard rings 220 that are adjacent to each other may be less than or equal to half a length (see L of FIG. 14), in the second direction D2, of the scribe lane area SL. Through this, damage applied to the main chip area MC while cutting the substrate 110 may be minimized.

In an example, each of the first guard ring 210 and the second guard ring 220 may include at least one of a metal and/or a nonmetal. The materials of the first guard ring 210 and the second guard ring 220 may be identical to each other and are not limited to a particular material. Here, the nonmetal may be plastic or rubber, for example.

In an example, the shapes of each of the first guard ring 210 and the second guard ring 220 are not particularly limited. For example, each of the first guard ring 210 and the second guard ring 220 separately may have the shape of a cylinder, a cone, a tube, a rectangular cuboid, a hexagonal prism, a square pyramid, a tetrahedron, or a triangular prism.

In an example, the semiconductor device 10 may include a low dielectric layer 160 disposed on the upper surface of the dielectric layer 150. The low dielectric layer 160 may be disposed between the dielectric layer 150 and the third insulating layer 170 and may be in contact with the dielectric layer 150.

In an example, the low dielectric layer 160 may include a low dielectric constant (low-k) material of which a dielectric constant is smaller than a dielectric constant of silicon dioxide (SiO₂).

In an example, the low dielectric layer 160 may perform a role of an adhesive layer which bonds the dielectric layer 150 and the third insulating layer 170 to each other.

In an example, the low dielectric layer 160 may include an inclined area in the scribe lane area SL. The inclined area in the low dielectric layer 160 may be formed in a cutting process and continue to decrease in thickness from the decreasing point P of thickness in the direction away from the main chip area MC.

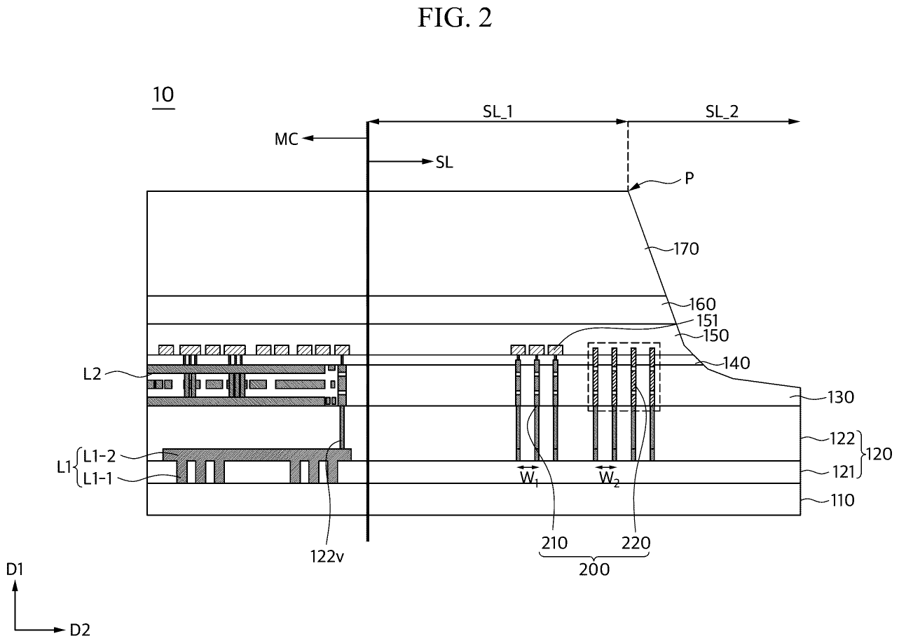

FIG. 2 illustrates the semiconductor device 10 according to an example embodiment of the present inventive concept and is a cross-sectional view showing the first guard ring 210 that penetrates a portion of the silicate layer 140 and the second guard ring 220 that penetrates a portion of the dielectric layer 150.

In an example, the second guard ring 220 may penetrate at least a portion of the silicate layer 140. Since the second guard ring 220 penetrates at least a portion of the silicate layer 140, interfacial delamination of the second insulating layer 130 may be prevented.

In an example, the second guard ring 220 may penetrate at least a portion of the dielectric layer 150. In this case, the second guard ring 220 may pass through the silicate layer 140. Through this, interfacial delamination of the second insulating layer 130 may be prevented.

In an example, at least a portion of the second guard ring 220 may penetrate a portion of the silicate layer 140 and at least another portion of the second guard ring 220 may penetrate a portion of the dielectric layer 150. For example, a first portion of the second guard ring 220 may penetrate at least a portion of the silicate layer 140 and a second portion of the second guard ring 220 may pass through the silicate layer 140 and penetrate at least a portion of the dielectric layer 150, without being limited to the drawing.

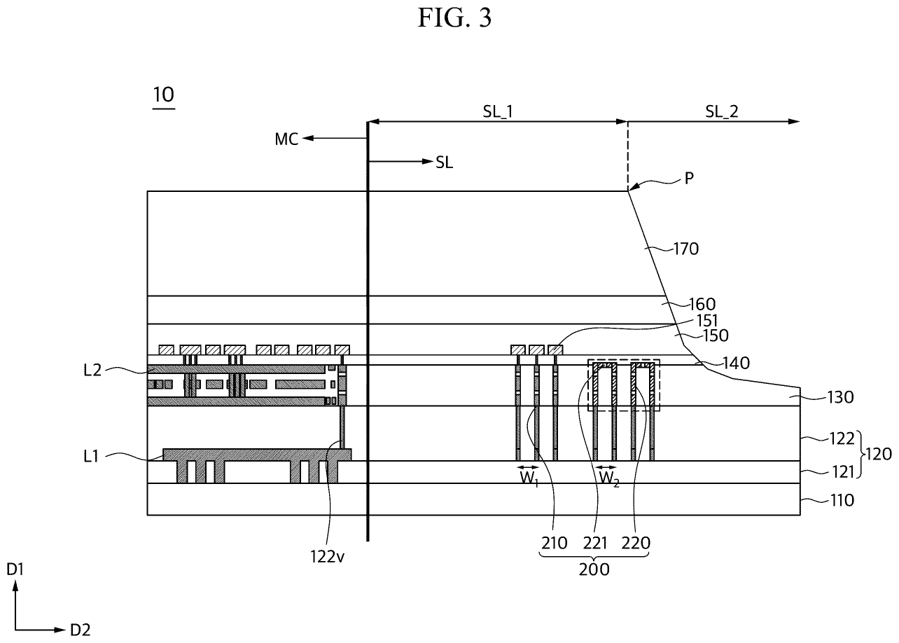

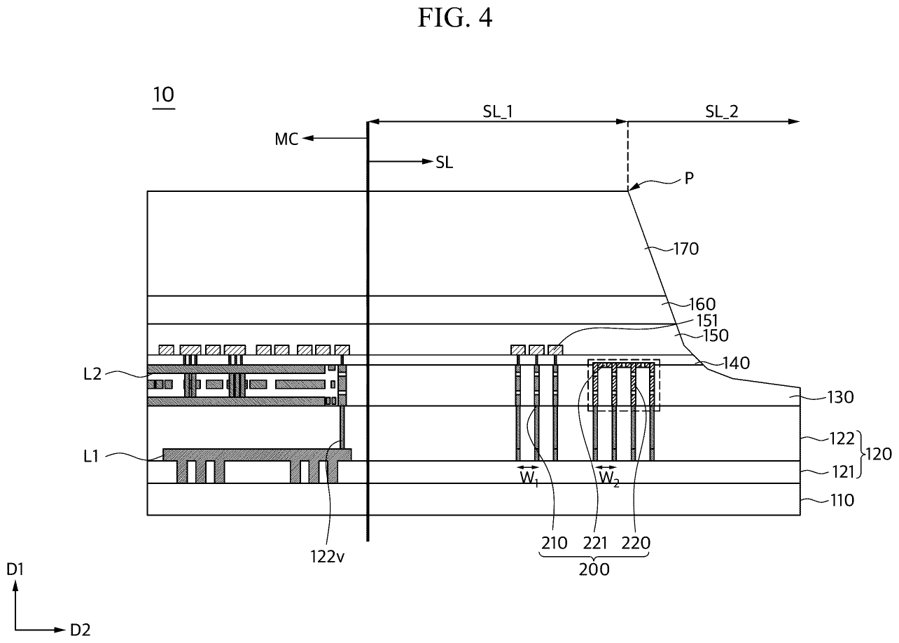

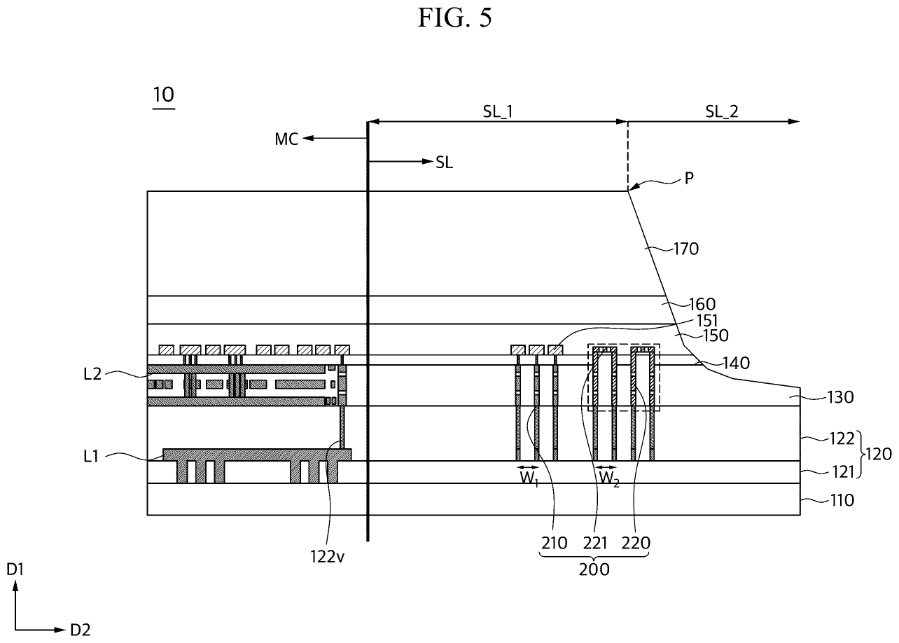

FIG. 3 is a cross-sectional view illustrating the semiconductor device 10 including a bridge 221 connecting the second guard rings 220, according to an example embodiment of the present inventive concept. FIG. 4 is a cross-sectional view illustrating the semiconductor device 10 including the bridge 221 connecting the second guard rings 220, according to an example embodiment of the present inventive concept. FIG. 5 is a cross-sectional view illustrating the semiconductor device 10 including the bridge 221 connecting the second guard rings 220 that penetrate a portion of the dielectric layer 150, according to an example embodiment of the present inventive concept.

In an example, the second guard rings 220 may be plural, and the guard ring 200 may include the bridge 221 connecting at least two of the second guard rings 220 to each other. A plurality of the second guard rings 220 is provided, and the plurality of guard rings 200 includes the bridge 221 configured to connect at least two of the plurality of second guard rings 220 to each other. The bridge 221 may be disposed to cover an area positioned at an uppermost end based on the first direction D1 considering the ease of production. However, the position of the bridge 221 is not particularly limited. For example, the bridge 221 may cover upper ends of the second guard rings 220; however, the present inventive concept is not limited thereto.

In an example, the second guard rings 220 and the bridge 221 may be integrally connected with each other. In another example, the bridge 221 may have through holes disposed in positions corresponding to the second guard rings 220 so that the second guard rings 220 may pass. In other words, the second guard rings 220 may be connected to the bridge 221 while passing through and being mounted into at least some of the through holes disposed in the bridge 221.

Referring to FIGS. 3 and 4, the second guard rings 220 may penetrate at least a portion of the silicate layer 140, and the bridge 221 may connect at least two of the second guard rings 220 to each other. Specifically, FIG. 3 illustrates two of the second guard rings 220 connected by the bridge 221, and FIG. 4 illustrates four of the second guard rings 220 connected by the bridge 221. The drawings illustrate merely examples, and the number of the second guard rings 220 connected to the bridge 221 is not particularly limited.

In an example, the number of through holes disposed in the bridge 221 may be more than or equal to the number of the second guard rings 220 to be connected. In addition, the size of the through holes disposed in the bridge 221 may be a size in which the second guard rings 220 may pass through at least some of the through holes and be mounted and combined thereto.

In an example, at least a portion of the bridge 221 may be embedded in the silicate layer 140. In addition, at least another portion of the bridge 221 may be embedded in the second insulating layer 130. In an example, the bridge 221 may be disposed to extend in a direction (that is, D2) parallel to a surface of the silicate layer 140.

Referring to FIG. 5, the second guard rings 220 may penetrate the silicate layer 140 and penetrate at least a portion of the dielectric layer 150, and the bridge 221 may connect at least two of the second guard rings 220 to each other.

In an example, at least a portion of the bridge 221 may be embedded in the dielectric layer 150. For example, an entire portion of the bridge 221 may be embedded in the dielectric layer 150. In an example, the bridge 221 may be disposed to extend in a direction (that is, D2) parallel to a surface of the dielectric layer 150.

In addition, in an example, a material of the bridge 221 may be identical to a material of the second guard rings 220.

In an example, a plurality of the second guard rings 220 may be disposed to extend in the first direction D1 perpendicular to the surface of the substrate 110 and disposed in parallel to each other with a predetermined gap therebetween based on the second direction D2 parallel to the surface of the substrate 110, and the bridge 221 may be disposed to extend in the second direction D2 and connected to the second guard rings 220. In other words, the second guard rings 220 and the bridge 221 may be connected to be perpendicular to each other. Through this, productivity may be secured for easy and efficient manufacturing process design, and an enlarged surface area may increase interfacial friction force, which may help increase product reliability by preventing interfacial delamination of the second insulating layer 130.

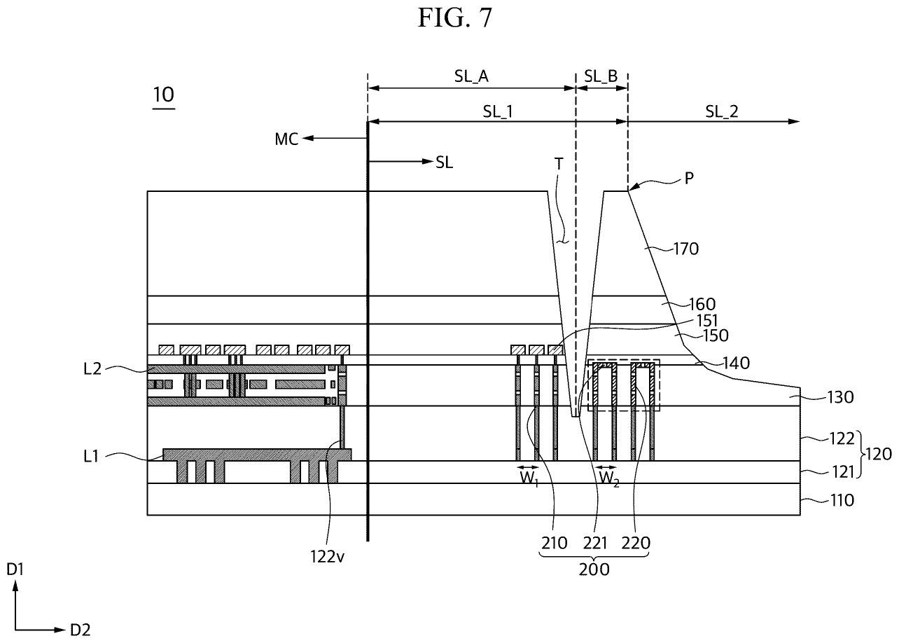

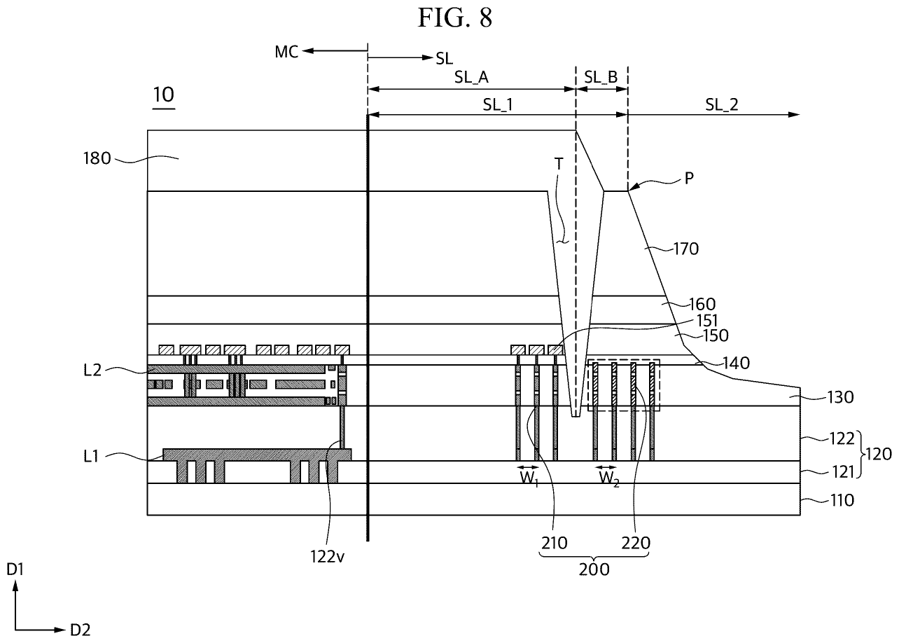

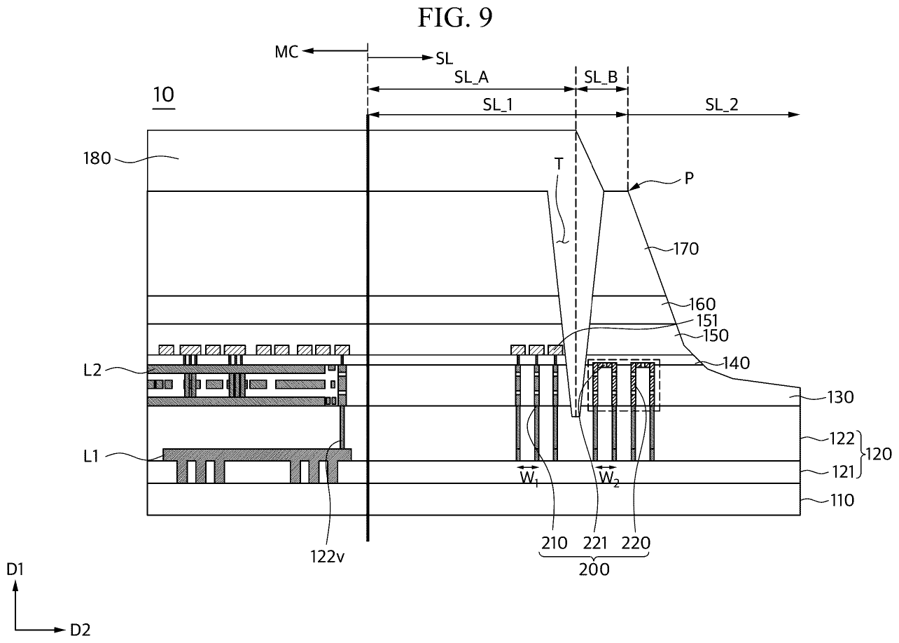

FIG. 6 is a cross-sectional view illustrating the semiconductor device 10 including the trench structure T, according to an example embodiment of the present inventive concept. FIG. 7 is a cross-sectional view illustrating the semiconductor device 10 including the trench structure T and the bridge 221 connecting the second guard rings 220, according to an example embodiment of the present inventive concept. FIG. 8 is a cross-sectional view illustrating the semiconductor device 10 including a photosensitive insulating film 180 filling the trench structure T, according to an example embodiment of the present inventive concept. FIG. 9 is a cross-sectional view illustrating the semiconductor device 10 including the photosensitive insulating film 180 filling the trench structure T and the bridge 221 connecting the second guard rings 220, according to an example embodiment of the present inventive concept.

In an example, the semiconductor device 10 may have the trench structure T, which penetrates the first insulating layer 120 and the second insulating layer 130, formed in the first area SL_1. The trench structure T may also penetrate the silicate layer 140, the dielectric layer 150, the low dielectric layer 160, and the third insulating layer 170.

In an example, the trench structure T may have a structure of penetrating from the third insulating layer 170, which is an uppermost end based on the first direction D1, to at least the second insulating layer 130. Through the trench structure T, damage applied to the scribe lane area SL while cutting the substrate 110 may be prevented from spreading to the main chip area MC.

In an example, the trench structure T may have a structure of penetrating from the third insulating layer 170 to a portion of the first insulating layer 120 based on the first direction D1 perpendicular to the surface of the substrate 110. Specifically, the trench structure T may penetrate a portion of the 1-2 insulating layer 122.

In an example, the trench structure T may have a structure of penetrating from the third insulating layer 170 to at least the second insulating layer 130 so that a portion of the third guard ring described above may be exposed. In addition, the first guard ring 210 and the second guard ring 220 might not be exposed by the trench structure T.

In an example, the trench structure T may gradually decrease in length in the second direction D2 as the trench structure T extends in a direction (that is, identical to the first direction D1) from the second insulating layer 130 to the first insulating layer 120.

In an example, the first area SL_1 may include an A area SL_A adjacent to the main chip area MC based on the trench structure T and a B area SL_B that is an area other than the A area SL_A. For example, the A area SL_A may be disposed between the main chip area MC and the B area SL_B. Here, the trench structure T may have a point at a deepest depth thereof, which may be referred to as a reference point, and the A area SL_A, which is adjacent to the main chip area MC, and the B area SL_B, which is far from the main chip area MC, may be divided based on the reference point in the second direction D2 parallel to the surface of the substrate 110. For example, a boundary between the A area SL_A and the B area SL_B may correspond to the reference point of the trench structure T.

In an example, the first guard ring 210 may be disposed in the A area SL_A. When a plurality of the first guard rings 210 are provided, all of the first guard rings 210 may be disposed in the A area SL_A.

In an example, at least one second guard ring 220 may be disposed in the B area SL_B. In other words, at least one second guard ring 220 disposed in the first area SL_1 described above may be disposed in the B area SL_B.

In addition, in an example, the first guard ring 210 and the second guard ring 220 may be divided according to positions. In other words, the guard ring 200 disposed in the A area SL_A of the first area SL_1 may be the first guard ring 210, and the guard ring 200 disposed in at least one of the B area SL_B of the first area SL_1 and the second area SL_2 may be the second guard ring 220.

In an example, the semiconductor device 10 may include the photosensitive insulating film 180 disposed on a portion of an upper surface of the third insulating layer 170. The photosensitive insulating film 180 may fill the trench structure T. The photosensitive insulating film 180 may include, but is not limited to, photosensitive polyimide, for example.

In an example, the photosensitive insulating film 180 might not be disposed in the second area SL_2. In addition, the photosensitive insulating film 180 may be disposed in a portion of the first area SL_1 and, specifically, may be disposed in an entire portion of the A area SL_A and a portion of the B area SL_B.

In an example, the photosensitive insulating film 180 might not be disposed in the decreasing point P of the thickness of the third insulating layer 170. In addition, the photosensitive insulating film 180 might not be disposed in an area beyond the trench structure T based on the second direction D2 parallel to the surface of the substrate 110.

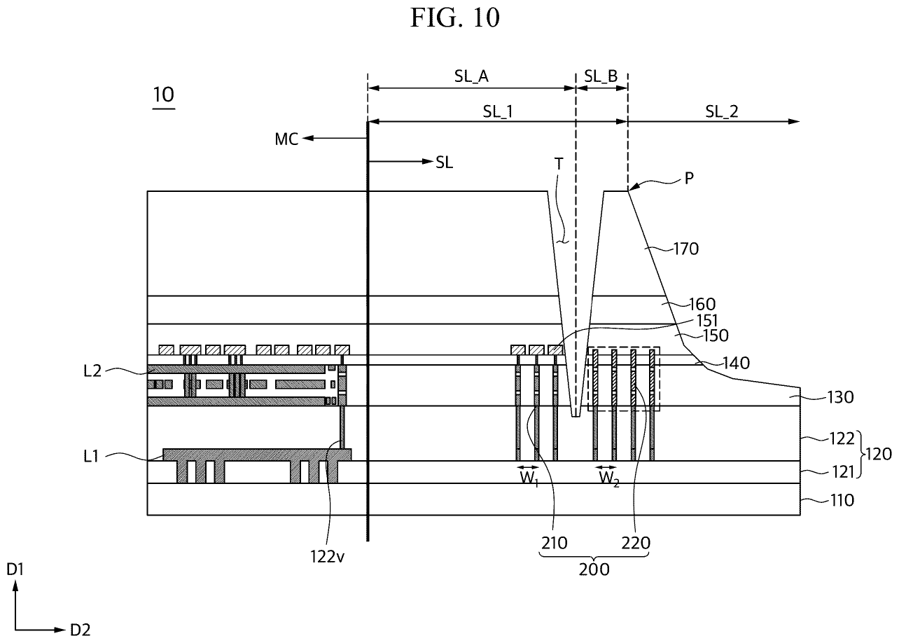

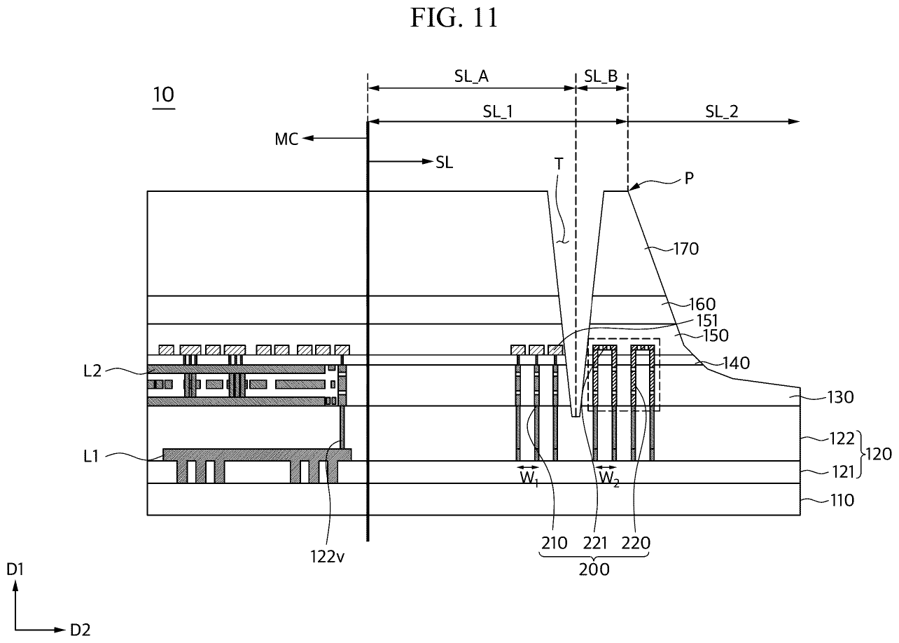

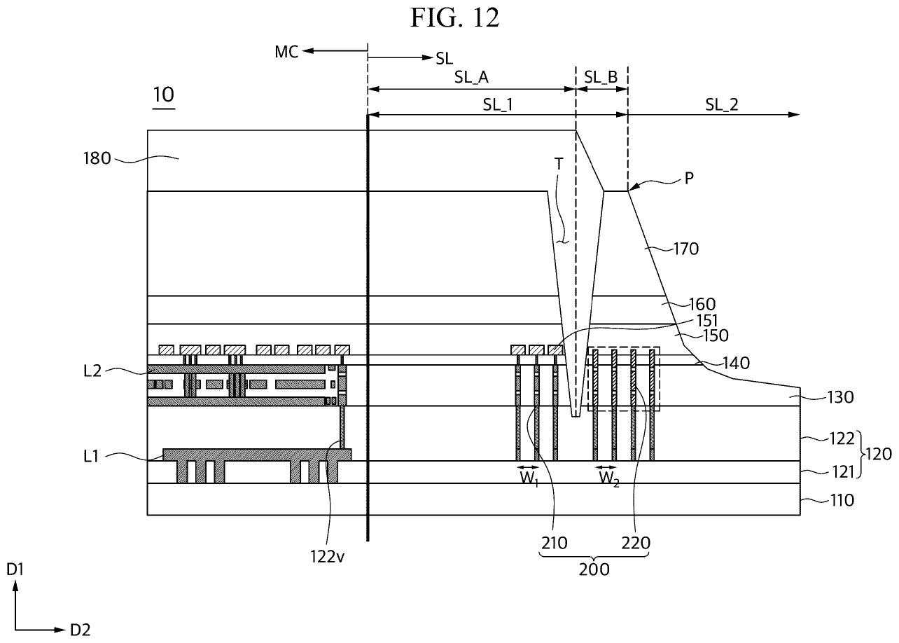

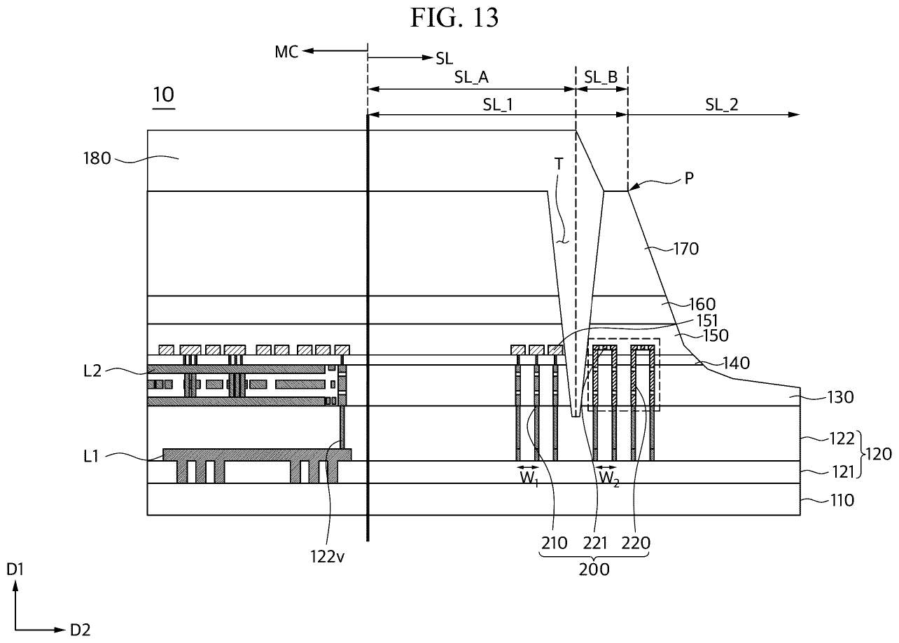

FIG. 10 is a cross-sectional view illustrating the semiconductor device 10 including the trench structure T and the second guard ring 220 that penetrates a portion of the dielectric layer 150, according to an example embodiment of the present inventive concept. FIG. 11 is a cross-sectional view illustrating the semiconductor device 10 including the trench structure T and the bridge 221 connecting the second guard rings 220 that penetrate a portion of the dielectric layer 150, according to an example embodiment of the present inventive concept. FIG. 12 is a cross-sectional view illustrating the semiconductor device 10 including the photosensitive insulating film 180 filling the trench structure T and the second guard ring 220 that penetrates a portion of the dielectric layer 150, according to an example embodiment of the present inventive concept. FIG. 13 is a cross-sectional view illustrating the semiconductor device 10 including the photosensitive insulating film 180 filling the trench structure T and the bridge 221 connecting the second guard rings 220 that penetrate a portion of the dielectric layer 150, according to an example embodiment of the present inventive concept.

The semiconductor device 10 illustrated in FIGS. 10 to 13 is merely different in that the second guard ring 220 penetrates the silicate layer 140 and penetrates at least a portion of the dielectric layer 150, compared to the semiconductor device 10 illustrated in FIGS. 6 to 9, and thus, the above descriptions may be referenced unless they are contradictory.

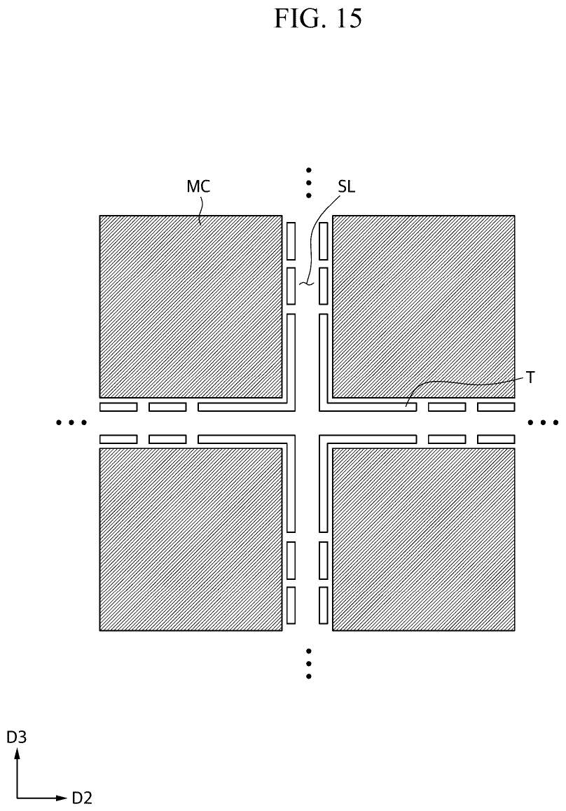

FIG. 14 is a top plan view illustrating the substrate 110 of the semiconductor device 10 according to an example embodiment of the present inventive concept. FIG. 15 is an enlarged top plan view illustrating the substrate 110 of the semiconductor device 10 according to an example embodiment of the present inventive concept.

In an example, when viewed from the first direction D1 perpendicular to the surface of the substrate 110, the trench structure T may be spaced apart from the main chip area MC by a predetermined distance. In addition, the trench structure T may surround at least a portion of a corner of the main chip area MC.

In an example, when viewed from the first direction D1 perpendicular to the surface of the substrate 110, the trench structure T may partially surround each corner of the main chip area MC, with similar structures positioned at all four corners.

Referring to a structure RB within a dashed line in FIG. 14, when viewed from the first direction D1 perpendicular to the surface of the substrate 110, the trench structure T may be spaced apart from the main chip area MC by a predetermined distance and surround a portion of each corner of the main chip area MC but be disposed in all corners.

In addition, referring to FIG. 14, the length L of the second direction D2 of the scribe lane area SL described above may indicate specifically a shortest distance between two main chip areas MC that are adjacent to each other.

FIG. 15 is an enlarged top plan view of a portion of FIG. 14, and referring to FIG. 15, a plurality of the trench structures T may be disposed on each corner of the main chip area MC. The plurality of the trench structures T may have a predetermined gap between adjacent trench structures T, and at least some gaps may be designed to be so sufficient that a terminal for product inspection or the like may be contactable without damaging the main chip area MC.

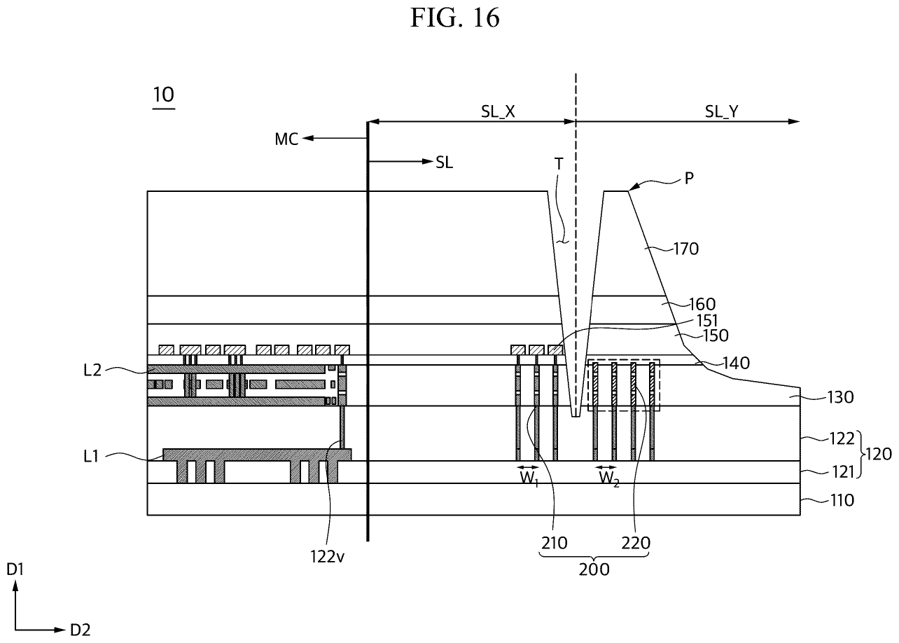

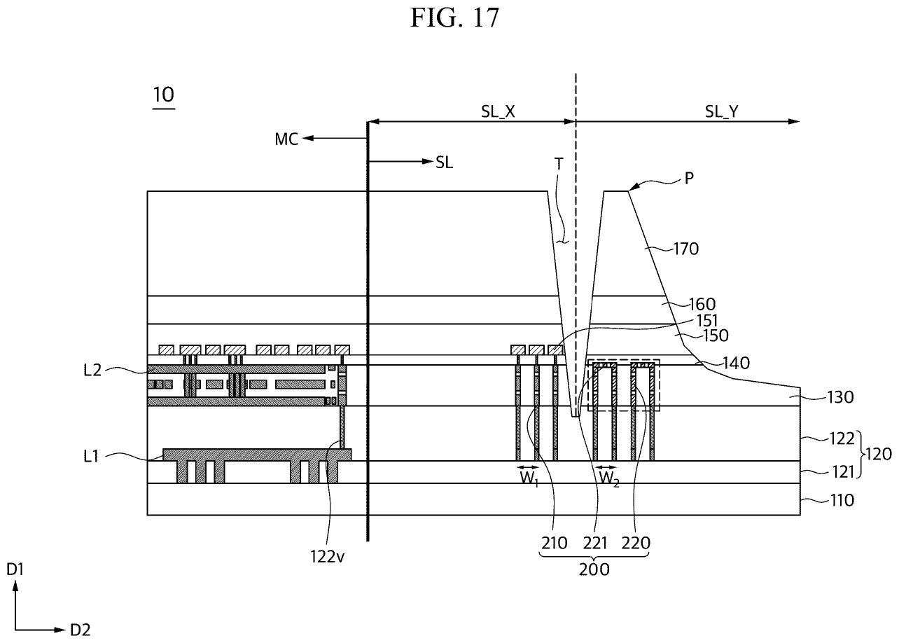

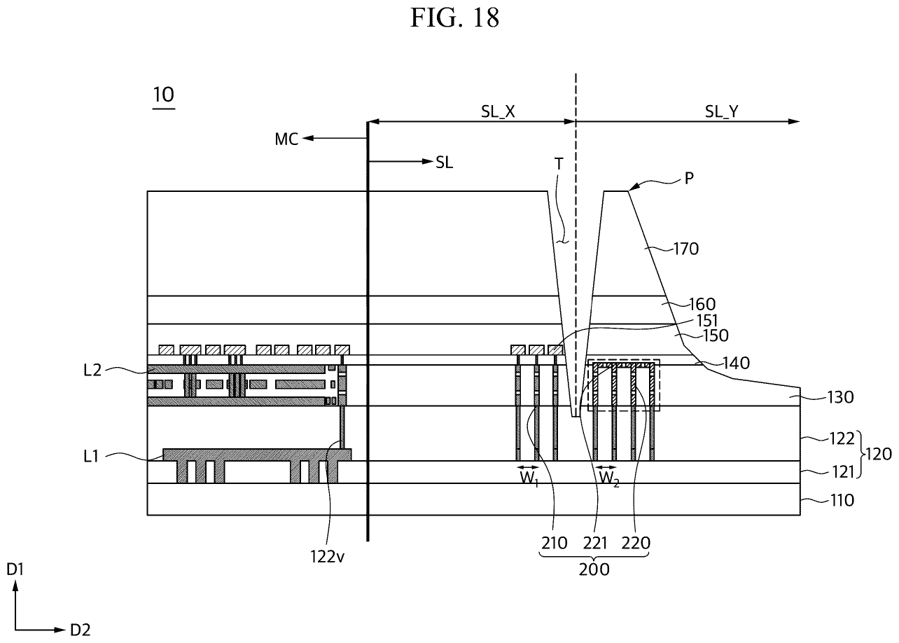

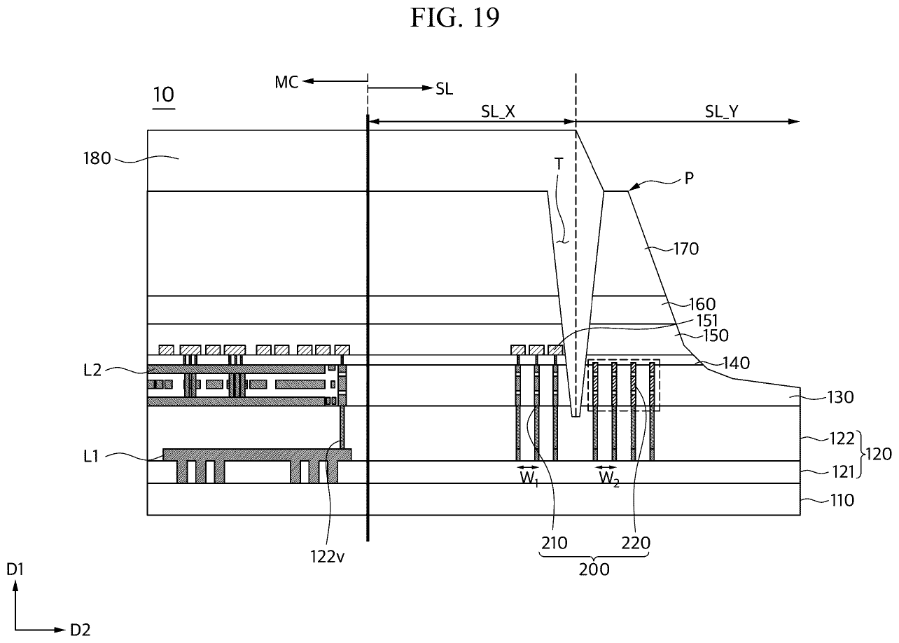

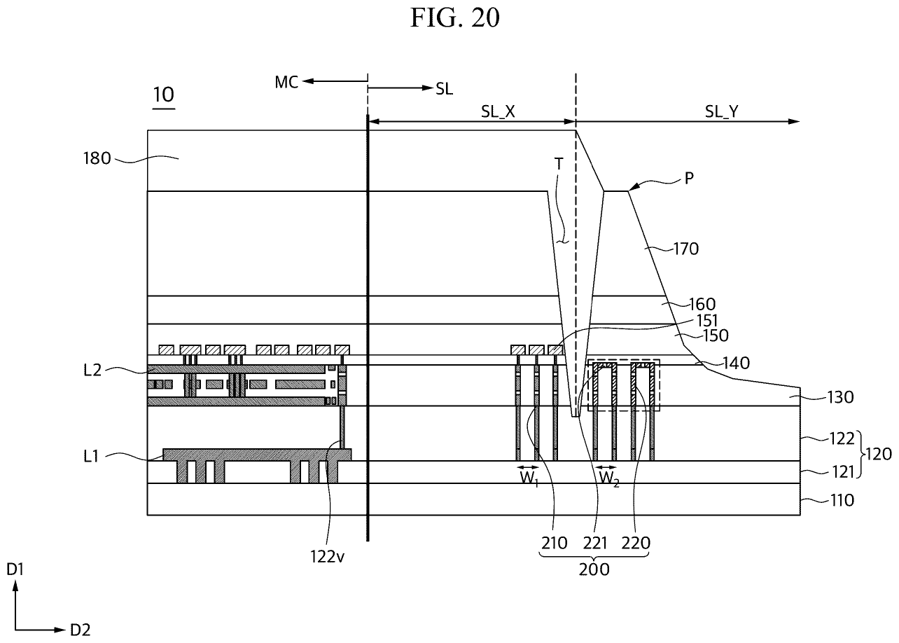

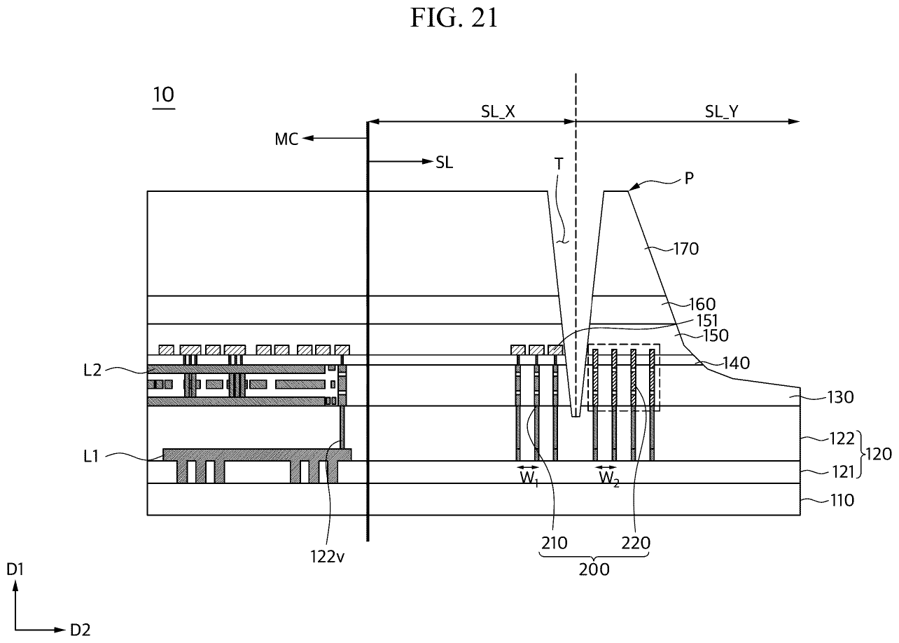

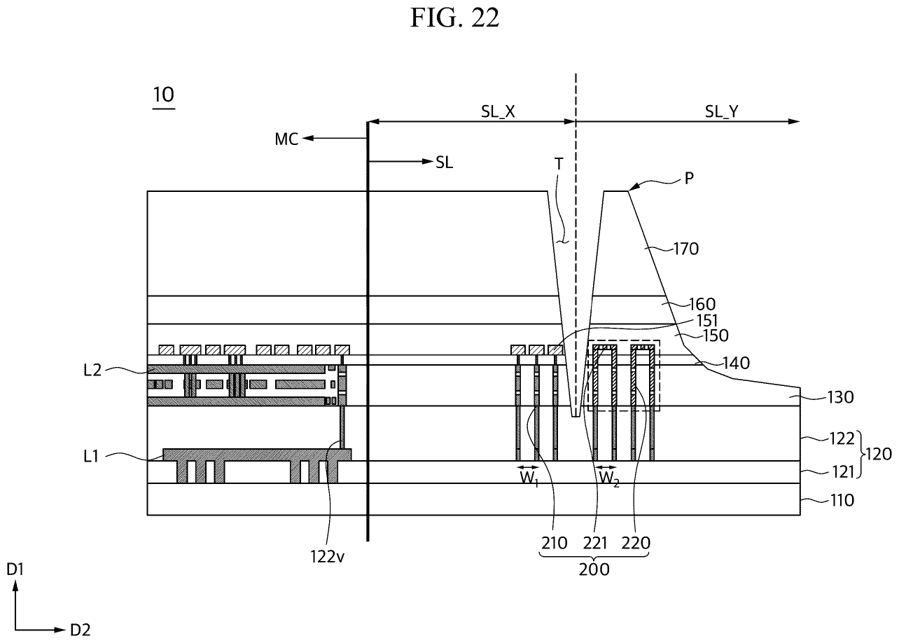

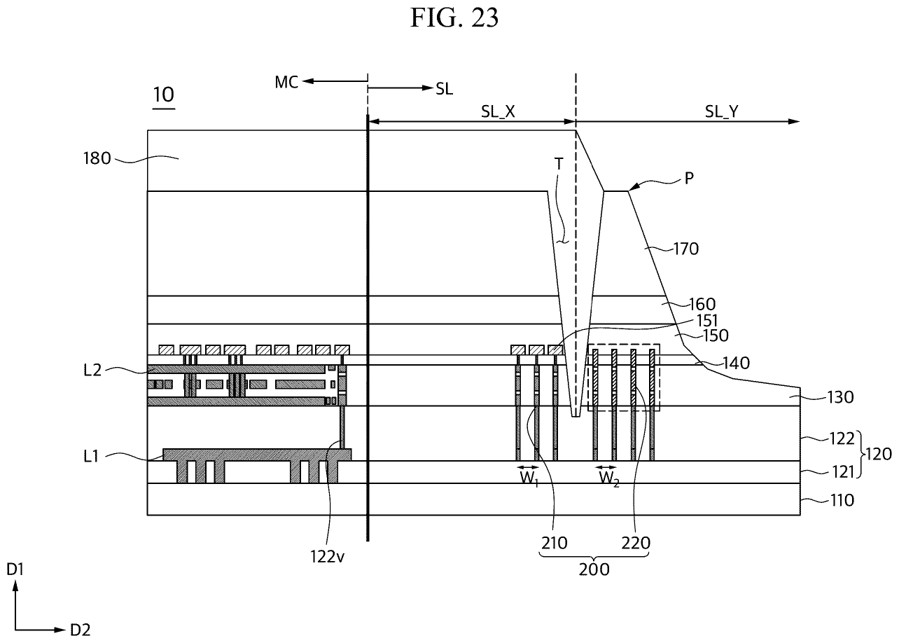

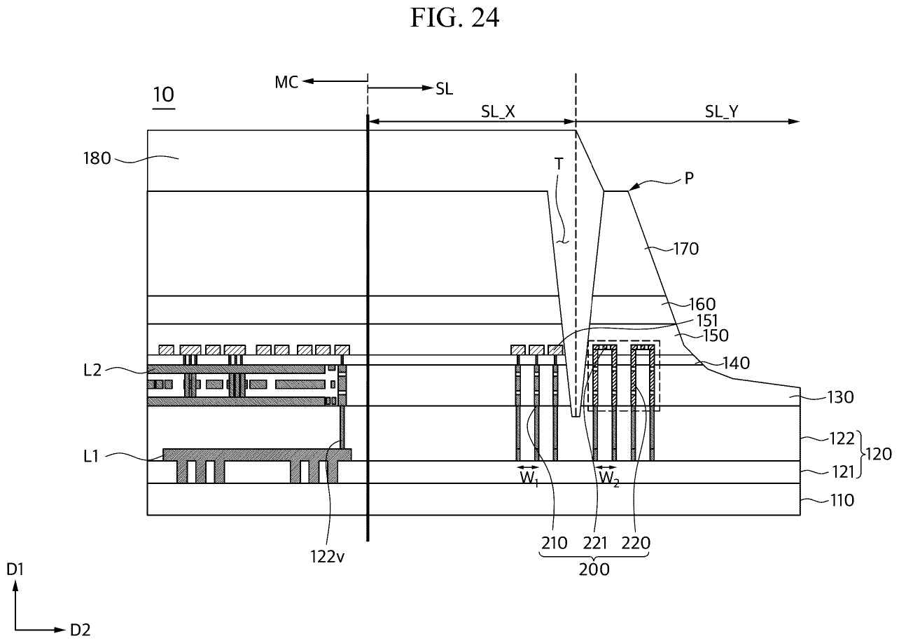

FIG. 16 is a cross-sectional view illustrating the semiconductor device 10 including the trench structure T, according to an example embodiment of the present inventive concept. FIG. 17 is a cross-sectional view illustrating the semiconductor device 10 including the trench structure T and the bridge 221 connecting the second guard rings 220, according to an example embodiment of the present inventive concept. FIG. 18 is a cross-sectional view illustrating the semiconductor device 10 including the trench structure T and the bridge 221 connecting the second guard rings 220, according to an example embodiment of the present inventive concept. FIG. 19 is a cross-sectional view illustrating the semiconductor device 10 including the photosensitive insulating film 180 filling the trench structure T, according to an example embodiment of the present inventive concept. FIG. 20 is a cross-sectional view illustrating the semiconductor device 10 including the photosensitive insulating film 180 filling the trench structure T and the bridge 221 connecting the second guard rings 220, according to an example embodiment of the present inventive concept. FIG. 21 is a cross-sectional view illustrating the semiconductor device 10 including the trench structure T and the second guard ring 220 that penetrates a portion of the dielectric layer 150, according to an example embodiment of the present inventive concept. FIG. 22 is a cross-sectional view illustrating the semiconductor device 10 including the trench structure T and the bridge 221 connecting the second guard rings 220 that penetrate a portion of the dielectric layer 150, according to an example embodiment of the present inventive concept. FIG. 23 is a cross-sectional view illustrating the semiconductor device 10 including the trench structure T and the second guard ring 220 that penetrates a portion of the dielectric layer 150, according to an example embodiment of the present inventive concept. FIG. 24 is a cross-sectional view illustrating the semiconductor device 10 including the trench structure T and the bridge 221 connecting the second guard rings 220 that penetrate a portion of the dielectric layer 150, according to an example embodiment of the present inventive concept.

FIGS. 16 to 24 merely has a difference in a manner of dividing the scribe lane area SL, compared to the semiconductor device 10 illustrated in FIGS. 6 to 13, and thus the above descriptions may be referenced unless they are contradictory (and the bridge 221 of FIG. 18 may be described with reference to the descriptions of FIG. 4). Hereinafter, the manner of dividing the scribe lane area SL is described in detail.

In an example, the scribe lane area SL may have the trench structure T formed and include an X area SL_X, which is adjacent to the main chip area MC based on the trench structure T, and a Y area SL_Y, that is an area other than the X area SL_X. For example, the X area SL_X may be disposed between the main chip area MC and the Y area SL_Y. Here, the trench structure T may have a point at a deepest depth thereof, which may be referred to as a reference point, and the X area SL_X, which is adjacent to the main chip area MC, and the Y area SL_Y, which is far from the main chip area MC, may be divided based on the reference point in the second direction D2 parallel to the surface of the substrate 110. Here, the guard ring 200 may include at least one or more first guard rings 210 disposed in the X area SL_X and at least one or more second guard rings 220 disposed in the Y area SL_Y.

In an example, the first guard ring 210 and the second guard ring 220 may be identified based on their positions. In other words, the guard ring 200 disposed in the X area SL_X may be the first guard ring 210, and the guard ring 200 disposed in the Y area SL_Y may be the second guard ring 220.

In an example, the decreasing point P of the thickness of the third insulating layer 170 may be disposed in the Y area SL_Y.

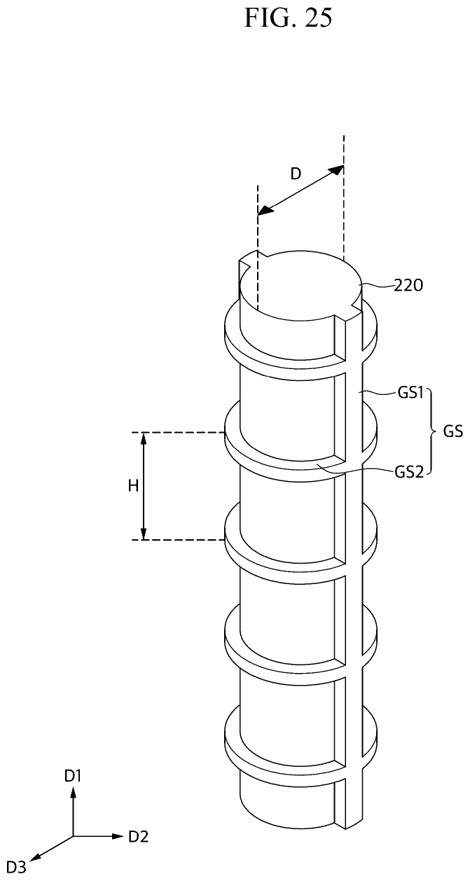

FIG. 25 is a perspective view illustrating the second guard ring 220 according to an example embodiment of the present inventive concept.

In an example, the second guard ring 220 may include a protrusion structure GS. The protrusion structure GS may enlarge a surface area of the second guard ring 220 to increase interfacial friction force, which may help increase product reliability by preventing interfacial delamination of the second insulating layer 130. For example, the protrusions GS may increase the surface area where the second guard ring 220 and second insulating layer 130 contact. This larger contact area may allow for friction forces to resist motion or separation between the second guard ring 220 and the second insulating layer 130. In addition, the increased interfacial friction force may prevent interfacial delamination of the insulating layer 130.

In an example, the protrusion structure GS may have any shape that may enlarge the surface area (for example, a surface area in contact with the second insulating layer 130) of the second guard ring 220 without being particularly limited. In an example, the protrusion structure GS may include an axial protrusion GS1 that extends in the first direction D1 perpendicular to the surface of the substrate 110. In addition, the protrusion structure GS may include a transverse protrusion GS2 that intersects the axial protrusion GS1.

In an example, the protrusion structure GS may include a plurality of the transverse protrusions GS2. The plurality of the transverse protrusions GS2 may be arranged such that each length H in the first direction D1 between the adjacent transverse protrusions GS2 is identical. For example, the length H may correspond to a gap between adjacent transverse protrusions GS2. For example, the length H in the first direction D1 between the adjacent transverse protrusions GS2 may be the length H in the first direction D1 between the adjacent transverse protrusions GS2 placed on a plane (for example, a plane defined by first and second directions D1 and D2 or plane defined by first and third directions D1 and D3) including the first direction D1.

In an example, the plurality of the transverse protrusions GS2 may have an area at which they are connected to each other. In addition, at least some of the plurality of the transverse protrusions GS2 may intersect the axial protrusion GS1.

In an example, a length D in the second direction D2, which is parallel to the surface of the substrate 110, in the second guard ring 220 may be substantially identical to the length H in the first direction D1 that is between the plurality of the transverse protrusions GS2. Through this, an enlarged surface area of the second guard ring 220 may increase interfacial friction force, which may help increase product reliability by preventing interfacial delamination. For example, the length D in the second direction D2 in the second guard ring 220 may be a diameter of a circle that is a bottom surface or a top surface when the second guard ring 220 is a cylindrical shape.

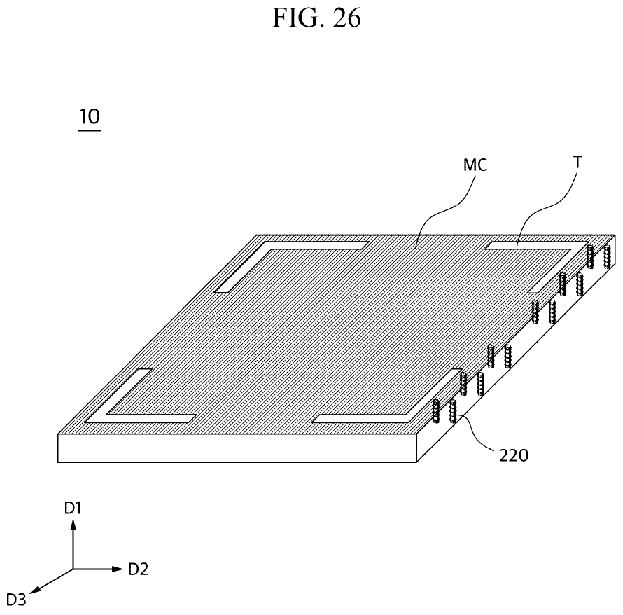

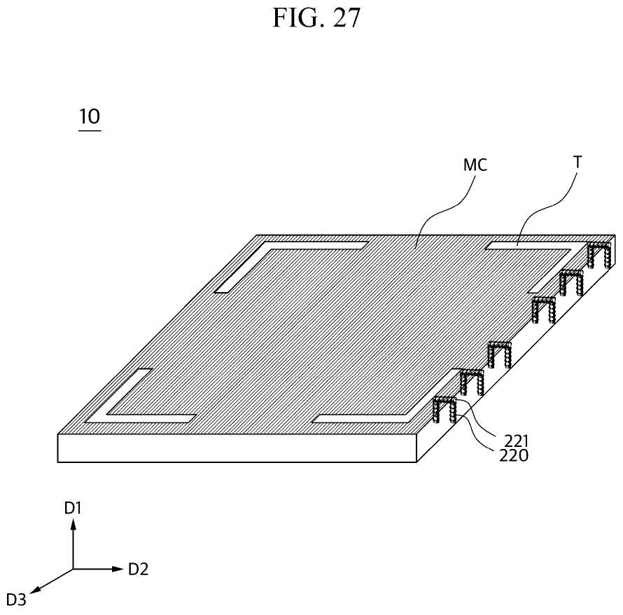

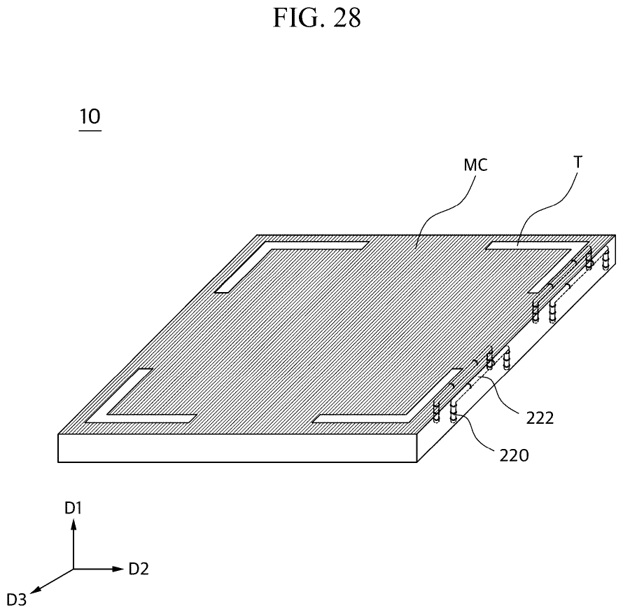

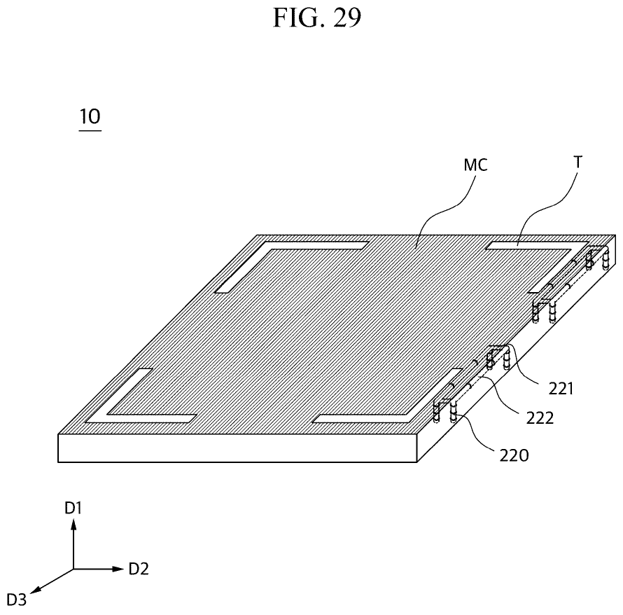

FIG. 26 is a perspective view illustrating the semiconductor device 10 including the second guard ring 220 (dotted line), according to an example embodiment of the present inventive concept. FIG. 27 is a perspective view illustrating the semiconductor device 10 including the second guard rings 220 (dotted line) connected by the bridge 221, according to an example embodiment of the present inventive concept. FIG. 28 is a perspective view illustrating the semiconductor device 10 including the second guard rings 220 (dotted line) connected by a bridge 222, according to an example embodiment of the present inventive concept. FIG. 29 is a perspective view illustrating the semiconductor device 10 including the second guard rings 220 (dotted line) connected by the bridges 221 and 222, according to an example embodiment of the present inventive concept.

In an example, the semiconductor device 10 may encompass both before and after cutting (specifically, cutting a scribe lane area) the substrate 110. Referring to FIGS. 14 and 15, the semiconductor device 10 before the substrate 110 cutting is shown. Referring to FIGS. 26 to 29, the semiconductor device 10 after the substrate 110 cutting is shown.

In an example, the second guard ring 220 may be disposed outside the trench structure T. In addition, the plurality of the second guard rings 220 may be connected by the bridges 221 and 222.

Referring to FIG. 27, the bridge 221 in an example may connect the plurality of the second guard rings 220 in the second direction D2 parallel to the surface of the substrate 110. In this case, the bridge 221 may be referred to as the first bridge 221.

As described above, the plurality of the second guard rings 220 in an example may be disposed to extend in the first direction D1 perpendicular to the surface of the substrate 110 and disposed in parallel to each other with a predetermined gap therebetween based on the second direction D2, and the first bridge 221 may be disposed to extend in the second direction D2 and connected to the second guard rings 220. For example, the first bridge 221 may connect a pair of second guard rings 220, which are adjacent to each other in the second direction D2, to each other.

Referring to FIG. 28, the bridge 222 in an example may connect the plurality of the second guard rings 220 in the third direction D3 that is a direction parallel to the surface of the substrate 110 and perpendicular to the second direction D2. In this case, the bridge 222 may be referred to as the second bridge 222.

In an example, the plurality of the second guard rings 220 may be disposed to extend in the first direction D1 perpendicular to the surface of the substrate 110 and disposed in parallel to each other with a predetermined gap therebetween based on the third direction D3, and the second bridge 222 may be disposed to extend in the third direction D3 and connected to the second guard rings 220. In other words, the second guard rings 220 and the second bridge 222 may be connected to be perpendicular to each other. For example, the second bridge 222 may connect a pair of second guard rings 220, which are adjacent to each other in the third direction D3, to each other in the third direction D3. Through this, productivity may be secured for easy and efficient manufacturing process design, and an enlarged surface area may increase interfacial friction force, which may help increase product reliability by preventing interfacial delamination of the second insulating layer 130.

Referring to FIG. 29, in an example, the first bridge 221 and the second bridge 222 may connect the plurality of the second guard rings 220 to each other in the second direction D2 and the third direction D3.

In an example, the plurality of the second guard rings 220 may be disposed to extend in the first direction D1 perpendicular to the surface of the substrate 110. At least some of the plurality of second guard rings 220 may be disposed in parallel to each other with a predetermined gap (e.g., a first predetermined gap) therebetween based on the second direction D2, and at least some others of the plurality of second guard rings 220 may be disposed in parallel to each other with a predetermined gap (e.g., a second predetermined gap) therebetween based on the third direction D3. Here, the first bridge 221 may be disposed to extend in the second direction D2 and connected to the at least some of the plurality of the second guard rings 220 having the first predetermined gap between each other based on the second direction D2, and the second bridge 222 may be disposed to extend in the third direction D3 and connected to the at least some others of the plurality of the second guard rings 220 having the second predetermined gap between each other based on the third direction D3. Through this, an enlarged surface area may increase interfacial friction force, which may help increase product reliability by preventing interfacial delamination of the second insulating layer 130.

In addition, in an example, the first bridge 221 and the second bridge 222 may be connected to each other. In addition, the first bridge 221 and the second bridge 222 may be connected to be perpendicular to each other. Through this, an enlarged surface area may increase interfacial friction force, which may help increase product reliability by preventing interfacial delamination of the second insulating layer 130.

While the present inventive concept has been described with reference to embodiments thereof, it will be understood by those of ordinary skill in the art that various changes in form and details may be made thereto without departing from the spirit and scope of the present inventive concept.

What is claimed is:

1. A semiconductor device comprising:
a substrate that includes a main chip area and a scribe lane area, wherein chip circuits, which include a first chip circuit and a second chip circuit, are disposed in the main chip area, and the scribe lane area is configured to surround the main chip area;
a first insulating layer that is disposed on the substrate and in which the first chip circuit is embedded;
a second insulating layer that is disposed on the first insulating layer and in which the second chip circuit and a plurality of guard rings are embedded;
a dielectric layer that is disposed on the second insulating layer and in which a metal plug is embedded; and
a third insulating layer that is disposed on the dielectric layer,
wherein the scribe lane area includes a first area and a second area, wherein the first area is adjacent to the main chip area based on a decreasing point of a thickness of the third insulating layer, and the second area is an area other than the first area,
wherein the plurality of guard rings includes a first guard ring and a second guard ring including a first second guard ring, wherein the first guard ring is connected to the metal plug, and the first second guard ring is not connected to the metal plug, and
wherein the first guard ring is disposed in the first area, and the first second guard ring is disposed in the second area.

2. The semiconductor device of claim 1, further comprising a silicate layer that is disposed between the second insulating layer and the dielectric layer and that is in contact with the second insulating layer,
wherein the first second guard ring is configured to penetrate at least a portion of the silicate layer.

3. The semiconductor device of claim 2, wherein the first guard ring is configured to penetrate at least a portion of the silicate layer.

4. The semiconductor device of claim 1, wherein the first second guard ring is configured to penetrate at least a portion of the dielectric layer.

5. The semiconductor device of claim 1, wherein the second guard ring further includes a second second guard ring that is disposed in the first area.

6. The semiconductor device of claim 5, wherein the first guard ring is disposed more adjacent to the main chip area than the second second guard ring.

7. The semiconductor device of claim 1, wherein a trench structure configured to penetrate the first insulating layer and the second insulating layer in the first area.

8. The semiconductor device of claim 7, wherein the first area includes an A area and a B area, wherein the A area is adjacent to the main chip area based on the trench structure, and the B area is an area other than the A area, and
wherein the first guard ring is disposed in the A area and the second guard ring is disposed in the B area.

9. The semiconductor device of claim 7, wherein the trench structure is configured to gradually decrease in length in a second direction, which is parallel to a surface of the substrate, as the trench structure extends in a direction from the second insulating layer to the first insulating layer.

10. The semiconductor device of claim 7, wherein, when viewed from a first direction perpendicular to a surface of the substrate, the trench structure is spaced apart from the main chip area by a predetermined distance and configured to surround at least a portion of a corner of the main chip area.

11. The semiconductor device of claim 7, further comprising a photosensitive insulating film disposed on a portion of the third insulating layer,
wherein the photosensitive insulating film is configured to fill the trench structure.

12. The semiconductor device of claim 1, wherein the second guard ring is of a plurality of second guard rings, and
wherein the plurality of guard rings further includes a bridge configured to connect at least two of the plurality of second guard rings to each other.

13. The semiconductor device of claim 1, wherein the second guard ring is of a plurality of second guard rings, and
wherein, based on a second direction that is parallel to a surface of the substrate, a gap between a pair of second guard rings, which are adjacent to each other, of the plurality of second guard rings is less than or equal to half a length in the second direction of the scribe lane area.

14. The semiconductor device of claim 1, wherein each of the first guard ring is of a plurality of first guard rings, and the second guard ring is plural of a plurality of second guard rings, and
wherein, based on a second direction that is parallel to a surface of the substrate, a gap between a pair of second guard rings, which are adjacent to each other, of the plurality of second guard rings is identical to a gap between a pair of first guard rings, which are adjacent to each other, of the plurality of first guard rings.

15. The semiconductor device of claim 1, wherein the second guard ring includes a protrusion structure.

16. The semiconductor device of claim 15, wherein the protrusion structure includes an axial protrusion and a transverse protrusion, wherein the axial protrusion is formed in a first direction that is perpendicular to a surface of the substrate, and the transverse protrusion intersects the axial protrusion.

17. The semiconductor device of claim 16, wherein the transverse protrusion is of a plurality of transverse protrusions, wherein the second guard ring includes the plurality of the transverse protrusions and a length in a second direction that is parallel to the surface of the substrate, wherein the length of the first second guard ring is identical to a length in the first direction that is between adjacent transverse protrusions of the plurality of the transverse protrusions.

18. A semiconductor device comprising:
a substrate that includes a main chip area and a scribe lane area, wherein chip circuits, which include a first chip circuit and a second chip circuit, are disposed in the main chip area, and the scribe lane area is configured to surround the main chip area;
a first insulating layer that is disposed on the substrate and in which the first chip circuit is embedded;
a second insulating layer that is disposed on the first insulating layer and in which the second chip circuit and a plurality of guard rings are embedded; and
a third insulating layer that is disposed on the second insulating layer,
wherein, in the scribe lane area, a trench structure configured to penetrate the first insulating layer and the second insulating layer is formed, and the scribe lane area includes an X area, which is adjacent to the main chip area based on the trench structure, and a Y area that is an area other than the X area,
wherein the plurality of guard rings includes a first guard ring and a second guard ring, and
wherein the first guard ring is disposed in the X area, and the second guard ring is disposed in the Y area.

19. The semiconductor device of claim 18, wherein a decreasing point of a thickness of the third insulating layer is disposed in the Y area.

20. A semiconductor device comprising:
a substrate that includes a main chip area and a scribe lane area, wherein chip circuits, which includes a first chip circuit and a second chip circuit, are disposed in the main chip area, and the scribe lane area is configured to surround the main chip area;
a first insulating layer that is disposed on the substrate and in which the first chip circuit is embedded;
a second insulating layer that is disposed on the first insulating layer and in which the second chip circuit and a plurality of guard rings are embedded;
a dielectric layer that is disposed on the second insulating layer and in which a metal plug is embedded;
a third insulating layer that is disposed on the dielectric layer;
a silicate layer that is disposed between the second insulating layer and the dielectric layer and that is in contact with the second insulating layer; and
a photosensitive insulating film disposed on a portion of the third insulating layer,
wherein a trench structure is formed in the scribe lane area, wherein the trench structure is configured to penetrate the first insulating layer and the second insulating layer, to gradually decrease in length in a first direction, which is parallel to a surface of the substrate, as the trench structure extends in a direction from the second insulating layer to the first insulating layer, and to surround at least a portion of a corner of the main chip area while being spaced apart from the main chip area,
wherein the scribe lane area includes an X area and a Y area, wherein the X area is adjacent to the main chip area based on the trench structure, and the Y area is an area other than the X area,
wherein the plurality of guard rings includes a first guard ring and a second guard ring,
wherein the first guard ring is disposed in the X area, and the second guard ring is disposed in the Y area,
wherein the first guard ring is configured to penetrate at least a portion of the second insulating layer,
wherein the second guard ring includes a protrusion structure and is configured to penetrate at least a portion of the silicate layer,
wherein the protrusion structure includes an axial protrusion and a transverse protrusion,
wherein the axial protrusion extends in a second direction intersecting the first direction, and the transverse protrusion intersects the axial protrusion,
wherein the second guard ring is of a plurality of second guard rings,
wherein the plurality of guard rings further includes a bridge configured to connect at least two of the plurality of second guard rings to each other, and
wherein the photosensitive insulating film is configured to fill the trench structure.
